(19) United States
(12) Patent Application Publication
(10) Pub. No.: US 2026/0228406 A1
(43) Pub. Date: Aug. 6, 2026

(54) SYSTEMS AND METHODS FOR TESTING PHYSICAL LAYOUTS FOR ELECTRONIC DESIGNS WITH SPEED AND ACCURACY

(71) Applicant: Motif Technology Inc., Los Gatos, CA (US)

(72) Inventors: Abdelsalam Mohamed ElTamawy, Cairo (EG); Amr Abuellil, Los Gatos, CA (US)

(21) Appl. No.: 19/046,391

(22) Filed: Feb. 5, 2025

(51) Int. Cl. G06F 30/392; G06F 30/398

(52) U.S. Cl. CPC G06F 30/392; G06F 30/398

(57) ABSTRACT

Systems and methods for forming a facet are described. The methods include receiving a selection of a plurality of zones within a schematic design of an integrated circuit. Any of the plurality of zones is unobfuscated and the plurality of zones are coupled to each other via a plurality of contextual connections. The methods further include identifying, from a layout design of the integrated circuit, a plurality of layout regions corresponding to the plurality of zones. The methods include coupling the plurality of layout regions via the plurality of contextual connections and forming the facet based on the plurality of layout regions and the plurality of contextual connections.

### FIELD

The present embodiments relate to systems and methods for testing physical layouts for electronic designs with speed and accuracy.

### BACKGROUND

An integrated circuit (IC), such as a semiconductor chip, has a large number of electronic components, such as transistors, logic gates, diodes, wires, etc., that are fabricated by forming layers of different materials and of different geometric shapes on various regions of a silicon wafer. To design the integrated circuit, a designer creates high level behavior descriptions of the IC using a high-level hardware design language. The high level behavior description of the IC device is translated into netlists of various levels of abstraction using a computer synthesis process. A netlist describes interconnections of components on the semiconductor chip and includes information of circuit primitives such as transistors and diodes, their sizes and interconnections, for example. The circuit design is then transformed into a geometric description called a layout. The layout is sometimes called a physical design. The result is a set of design files. With respect to the design, testing, and implementation of the IC, electronic design automation (EDA) tools are used. However, with a decrease in a size of the semiconductor chip and given a large numbers of circuit elements in the IC, it is more difficult to test the IC in a desirable manner.

It is in this context that embodiments described in the present disclosure arise.

### SUMMARY

Embodiments of the disclosure provide systems and methods for testing physical layouts for electronic designs with speed and accuracy. It should be appreciated that the present embodiments can be implemented in numerous ways, e.g., a process, an apparatus, a system, a piece of hardware, or a method on a computer-readable medium. Several embodiments are described below.

In one embodiment, the systems and methods, described herein, are used to accelerate post layout verification in the electronic designs and used for both debugging root causes and speeding up simulations.

In an embodiment, a method for forming a facet is described. The method includes receiving a selection of a plurality of zones within a schematic design of an integrated circuit. Any of the plurality of zones is unobfuscated and the plurality of zones are coupled to each other via a plurality of contextual connections. The method further includes identifying, from a layout design of the integrated circuit, a plurality of layout regions corresponding to the plurality of zones. The method includes coupling the plurality of layout regions via the plurality of contextual connections and forming the facet based on the plurality of layout regions and the plurality of contextual connections.

In one embodiment, a controller for generating a facet is described. The controller includes a processor. The processor receives a selection of a plurality of zones within a schematic design of an integrated circuit. Any of the plurality of zones is unobfuscated. The plurality of zones are coupled to each other via a plurality of contextual connections. The processor identifies, from a layout design of the integrated circuit, a plurality of layout regions corresponding to the plurality of zones. The processor couples the plurality of layout regions via the plurality of contextual connections and forms the facet based on the plurality of layout regions and the plurality of contextual connections. The controller includes a memory device coupled to the processor.

In an embodiment, a system for generating a facet is described. The system includes a computer. The computer receives a selection of a plurality of zones within a schematic design of an integrated circuit. Any of the plurality of zones is unobfuscated and the plurality of zones are coupled to each other via a plurality of contextual connections. The system includes a server coupled to the computer via a computer network. The server identifies, from a layout design of the integrated circuit, a plurality of layout regions corresponding to the plurality of zones. The server couples the plurality of layout regions via the plurality of contextual connections and forms the facet based on the plurality of layout regions and the plurality of contextual connections.

Some advantages of the herein described systems and methods include generating the facet based on a schematic design of an integrated circuit and a layout design of the integrated circuit. To generate the facet, the schematic design stored in an arrow columnar format in one or more databases is accessed. The arrow columnar format facilitates speedy access of the schematic design from the one or more databases. A user selects the zones within the schematic design that is accessed from the one or more databases. Contextual connections are provided between the zones. There is no black boxing of circuit elements of the schematic design and no black boxing of the contextual connections to preserve accuracy in testing the facet. The contextual connections are not hardware or physical connections but are interactive connections between the zones. For example, the interactive connections include electromagnetic coupling between the zones and the systems and methods, described herein, model the electromagnetic coupling. As another example, the interactive connections include parasitic capacitances or parasitic coupling or any other nonphysical interactions between circuit elements of the zones. When the zones are selected, an arrow columnar format of the layout design stored in the one or more databases is accessed to identify layouts correlated to the zones and the contextual connections are applied to the layouts. By applying the contextual connections, accuracy in generating the facet and testing the facet is maintained. The facet is generated as including the layouts and the contextual connections and is then tested.

It should be appreciated that the present embodiments can be implemented in numerous ways, e.g., a process, an apparatus, a system, a piece of hardware, or a method on a computer-readable medium. Several embodiments are described below. Other aspects will become apparent from the following detailed description, taken in conjunction with the accompanying drawings.

### BRIEF DESCRIPTION OF THE DRAWINGS

The embodiments are understood by reference to the following description taken in conjunction with the accompanying drawings.

FIG. 1A is a diagram of an embodiment of a system to illustrate preprocessing of schematic files and layout files.

FIG. 1B-1 is a diagram of an embodiment of multiple tree structures, and of an embodiment of an intermediate representation of a schematic design.

FIG. 1B-2 is a diagram of an embodiment of an intermediate representation of a layout design.

FIG. 1C-1 is a diagram of an embodiment of a system to illustrate facet generation.

FIG. 1C-2 is a diagram of an embodiment of an arrow columnar format that is generated from the intermediate representation of the schematic design.

FIG. 1C-3 is a diagram of an embodiment of an arrow columnar format that is generated from the intermediate representation of the layout design.

FIG. 2A is a diagram of an embodiment of a system to illustrate generation of a facet.

FIG. 2B is a flowchart of an embodiment of a method for identifying a correlation between a zone selected from the schematic design and a layout corresponding to the zone.

FIG. 3 is a diagram of an embodiment of a system to illustrate an operation of unifying grammars from the schematic files.

FIG. 4A is a diagram of an embodiment of a system to illustrate generation of a facet based on zones that are selected by a user.

FIG. 4B is a diagram of an embodiment of a system to illustrate that a different verification scenario is created for simulation than a verification scenario illustrated by the system of FIG. 4A.

FIG. 5 is a diagram of an embodiment of a system to illustrate propagation resolution, data preprocessing, materialization, and netlist statistics and analytics.

FIG. 6 is a diagram of an embodiment of a system to illustrate a debugging iterations tool.

### DETAILED DESCRIPTION

The following embodiments describe systems and methods for testing physical post layout performance for electronic designs in microchips with speed and accuracy. It will be apparent that the present embodiments may be practiced without some or all of these specific details. In other instances, well known process operations have not been described in detail in order not to unnecessarily obscure the present embodiments.

In an embodiment, the electronic designs are of integrated circuits, such as blocks to larger system-on-chips (SoCs). As an example, a block is a functional unit or a component within a larger system, such as an SoC. To illustrate, blocks are sub-circuits or modules that perform specific tasks. To further illustrate, in an SoC, a block is a central processing unit (CPU) core, a graphics processing unit (GPU), a memory controller, an audio codec, or a power management unit. As another further illustration, a block is an analog circuit component, such as a resistor, an inductor, a transistor, a capacitor, an amplifier, a comparator, a clock generator, a voltage reference circuit, an analog-to-digital converter, or a digital-to-analog converter. As an example, an SoC is a complete integrated circuit that contains most or all of the components, such as blocks, for a complete functional system, all embedded into a single chip. To illustrate, in an SoC, blocks function together to provide a functionality, such as, processing power, storage, networking, audio, or video, or a combination thereof, and other features found in devices like smartphones, tablets, or internet of things (IoT) devices. As another illustration, in an SoC, blocks are coupled with each other to provide functionality, such as, reducing an amount of power that is output from the SoC or increasing an amount of power that is output from the SoC or matching an amount of power output from the SoC with an amount output from another SoC. To further illustrate, blocks of an SoC are coupled to each other to create an analog processor for modulation or demodulation or network communication, or create an analog global positioning system (GPS), or create an analog sensor, or create an IoT device, or a create consumer electronic item, or create a smart home device, or create a wearable device, or create a health device.

The systems and methods described herein generate one or more facets that can be tested. In the systems and methods, an intermediate representation of a schematic design of an integrated circuit is generated based on netlists of the schematic design in multiple schematic files. The intermediate representation of the schematic design is then converted into an arrow columnar format. The arrow columnar format of the schematic design is stored in one or more databases. Also, an intermediate representation of a layout design of the integrated circuit is generated based on netlists of the layout design and multiple layout files. The intermediate representation of the layout design is converted into an arrow columnar format, which is stored in the one or more databases. Also, correlations between each of multiple circuit elements of the schematic design and a respective one of layouts of the layout design are generated and stored in the one or more databases. A user selects the schematic design from the one or more databases. When the schematic design is selected from the one or more databases, a computer accesses the arrow columnar format of the schematic design from the one or more databases to display the schematic design. The arrow columnar format of the schematic design facilitates speedy access of the schematic design from the one or more databases. The user selects multiple zones of the schematic design via the computer. When the schematic design is accessed, contextual connections between two of the zones are accessed from the arrow columnar format of the schematic design. Based on the zones, the arrow columnar formats of the schematic and layout designs are accessed from the one or more databases to identify multiple layouts that correlate to the zones. The arrow columnar format of the layout design facilitates speedy access of the layout design from the one or more databases. The contextual connections are preserved between the layouts by generating the contextual connections between the layouts. The facet is generated as including the layouts and the contextual connections. The facet is then tested to determine whether structure and/or functionality of the facet is valid. By preserving the contextual connections, accuracy in testing the facet is achieved.

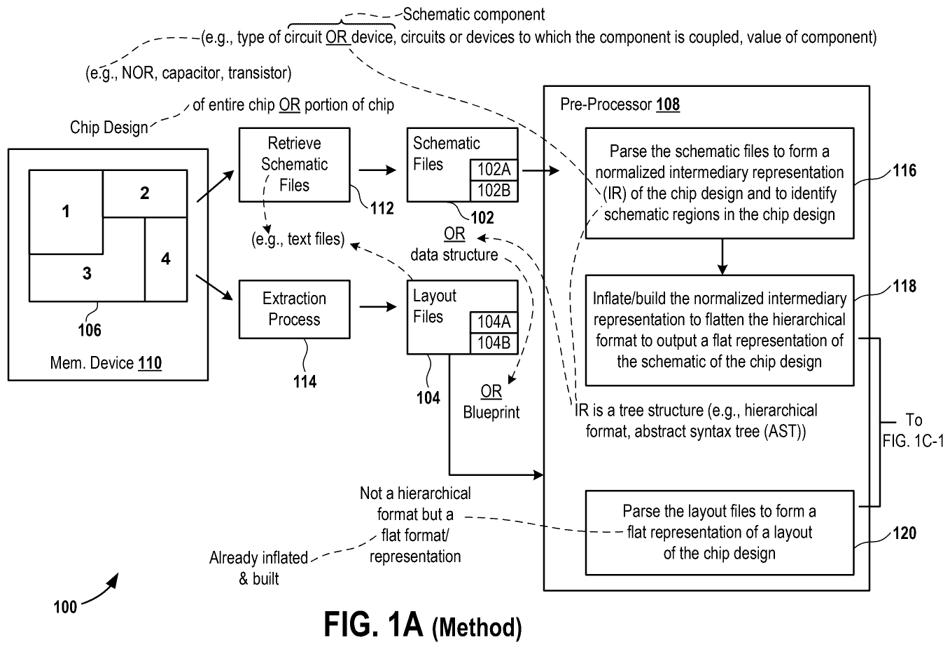

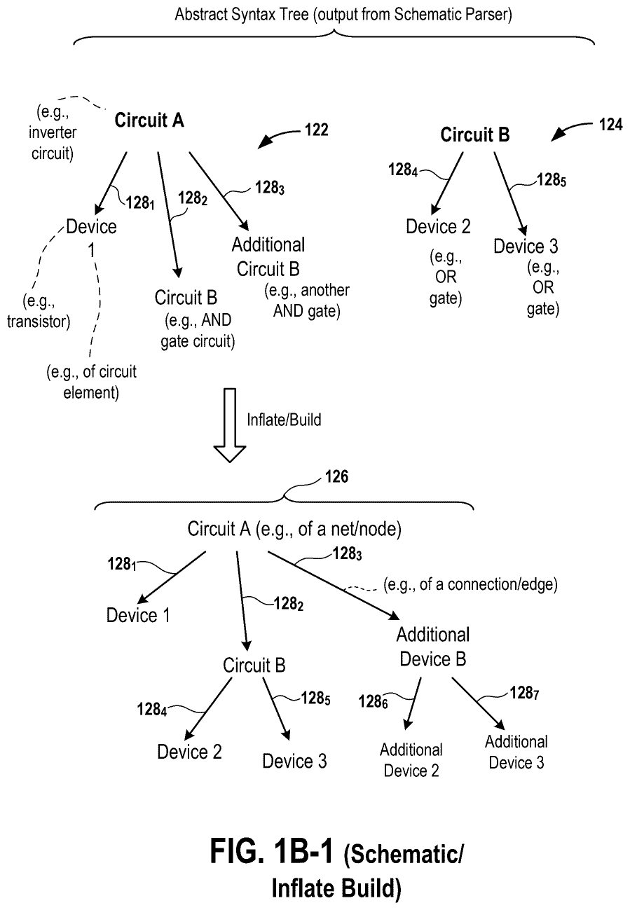

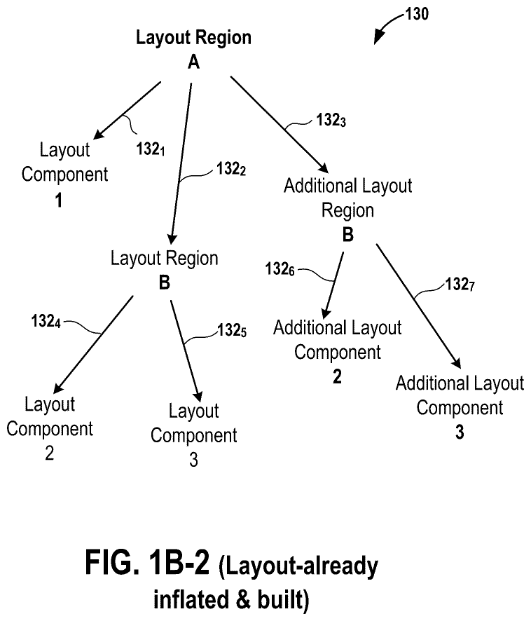

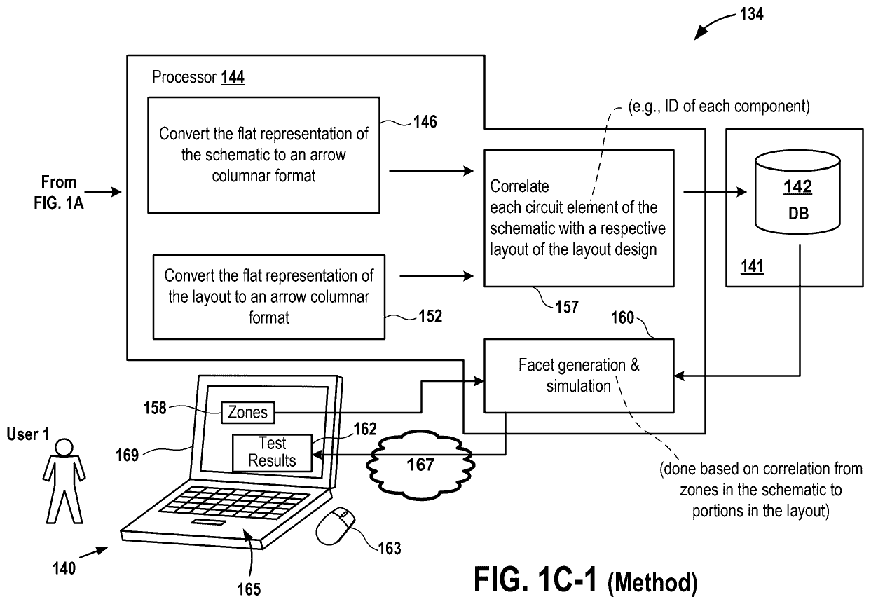

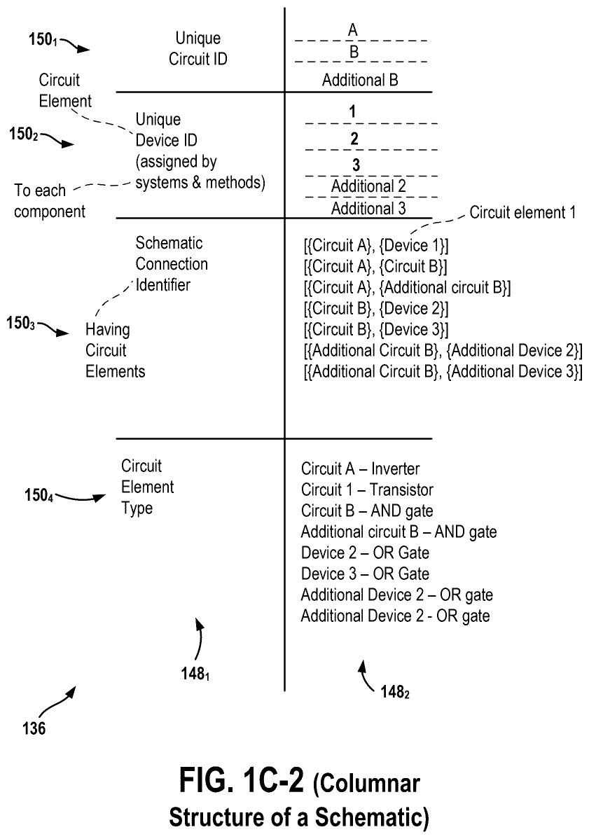

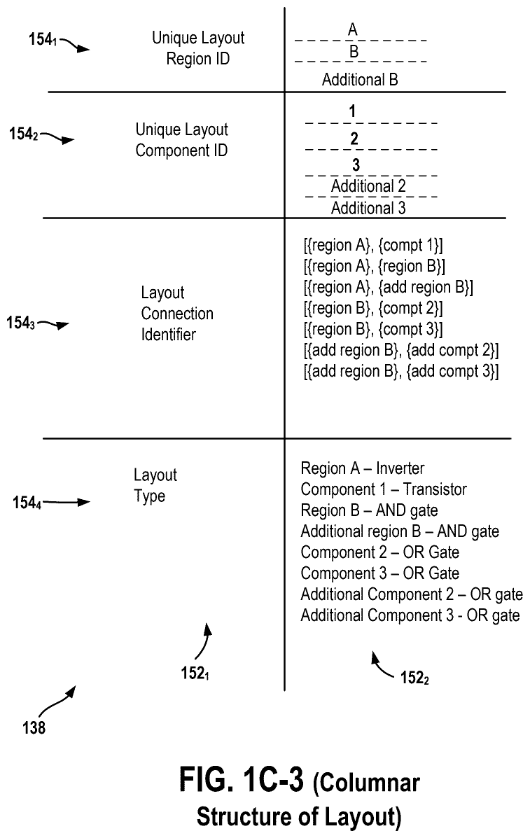

FIG. 1A is a diagram of an embodiment of a system 100 to illustrate preprocessing of schematic files 102 and layout files 104. The system 100 includes a chip design 106 of an integrated circuit, such as a 5 nanometer (nm) chip or a 4 nm chip or a 3 nm chip or a 2 nm chip, or a portion of the integrated circuit. The chip design 106 includes a schematic design and a layout design of the integrated circuit or the portion of the integrated circuit. As an example, the layout design has geometric shapes which correspond to patterns of metal, oxide, or semiconductor layers that form layouts of circuit elements of the integrated circuit. An example of the integrated circuit includes a system on a chip (SoC), such as an application specific integrated circuit (ASIC) or a programmable logic device (PLD) or a memory chip. To illustrate, the integrated circuit is a microchip or a processor or a microcontroller or a computer chip or an analog circuit or a digital circuit. To further illustrate, the integrated circuit includes circuit elements, such as logic gates, switches, voltage sources, ground potentials, multiplexers, demultiplexers, processors, memory devices, interconnects, clock sources, digital signal sources, radio frequency (RF) signal sources, counters, registers, flip-flops, latches, clock generators, voltage reference circuits, amplifiers, pin ins, pin outs, batteries, transistors, diodes, counters, resistors, transformers, inductors, and capacitors, and connections, such as hardware metal connections, between the circuit elements. It should be noted that resistors, capacitors, diodes, comparators, clock generators, voltage reference circuits, amplifiers, and inductors are examples of analog circuit elements, such as blocks. Also, a transistor is an example of an analog circuit element or a digital circuit element. It should further be noted that logic gates, flip-flops, latches, and counters are examples of digital circuit elements. As an example, a digital circuit element produces a binary signal representing 1s and 0s, and an analog circuit element produces a continuous signal, such as a sine wave signal. The schematic design is of the circuit elements in that the schematic design includes representations, such as circuit symbols, of the circuit elements. In the further illustration, some of the circuit elements are etched onto a small piece of semiconductor material, such as silicon. Examples of the logic gates include an AND gate, an OR gate, a NOR gate, and a NAND gate. Each of the AND gate, the OR gate, the NOR gate, and the NAND gate is a type of logic gate. The integrated circuit is used in a variety of electronic devices, such as digital cameras, sensors, smart phones, computers, tablets, and televisions. Additional examples of the integrated circuit includes analog processors, amplifiers, comparators, clock generators, and voltage reference circuits.

The system 100 further includes a preprocessor 108. Examples of a processor, as used herein, include an integrated circuit, a microprocessor, a microcontroller, and a central processing unit (CPU). The system 100 further includes a memory device 110 in which the chip design 106 is stored. For example, the schematic files 102 and the layout files 104 are stored in the memory device 110. To illustrate, the schematic files 102 and the layout files 104 are portions of process design kits (PDKs) received from one or more entities, such as foundries. To further illustrate, the schematic files 102 include a schematic file 102A and another schematic file 102B and the layout files 104 include a layout file 104A and another layout file 104B. In the further illustration, the schematic files 102 include textual representations, such as netlists, of the schematic design and the layout files 104 include textual representations of the layout design. The schematic file 102A and the layout file 104A are portions of a first PDK from a first foundry and the schematic file 102B and the layout file 104B are portions of a second PDK from a second foundry. In the further illustration, the files 102A and 104A include the chip design 106 and the files 102B and 104B also include the chip design 106. In the further illustration, the file 102A uses different grammar than that used in the file 102B to represent the schematic design. Examples of the different grammar are provided below.

The preprocessor 108 executes an operation 112 of retrieving, such as reading or accessing, the schematic files 102 from the memory device 110 and executes an extraction process 114 of retrieving the layout files 104 from the memory device 110. The memory device 114 is a part of the system 100. To illustrate, the memory device 114 is a part of a server system, described below. Examples of a memory device include a read-only memory or a random access memory. To illustrate, a memory device is a Flash memory or a redundant array of storage disks. An example of a combination of a processor and a memory device, as described herein, is a controller.

Upon retrieving the schematic files 102, in an operation 116, the preprocessor 108 parses, such as analyzes or traverses, the schematic file 102 to translate, such as convert, different types of grammar of the schematic files 102 into a normalized intermediary representation (IR) of the schematic design and to identify schematic regions, such as circuit elements and schematic connections between the circuit elements, within the schematic design. For example, the preprocessor 108 identifies from a first type of grammar of a first one of the schematic files 102 a number of circuit elements, a number of inputs to each of the circuit elements, a number of outputs from each of the circuit elements, schematic connections between the circuit elements, values of the circuit elements, and assigns identifiers (IDs) to the circuit elements. To illustrate, a value of a circuit element includes an inductance of an inductor, or a capacitance of a capacitor, or a resistance of a resistor, or a voltage output from a voltage source, or a voltage output from a battery. In the example, an input to a circuit element is a portion of the circuit element, an output from the circuit element is a portion of the circuit element, and a value of the circuit element is a portion of the circuit element. Examples of the normalized IR generated from the schematic files 102 are provided below. Also, the normalized IR generated from the schematic files 102 is sometimes referred to herein as a schematic blueprint or a hierarchical representation.

Further in the example, the preprocessor 108 identifies from a second type of grammar of a second one of the schematic files 102, the number of circuit elements, the number of inputs to each of the circuit elements, the number of outputs from each of the circuit elements, and the schematic connections between the circuit elements. Continuing with the example, the preprocessor 108 generates the normalized IR having multiple tree structures, such as hierarchical formats or syntax trees, in which the circuit elements are represented as nodes, the schematic connections between the circuit elements are represented as lines or directional arrows. The lines or directional arrows are examples of edges.

Also in the example, the preprocessor 108 identifies a first group from the circuit elements and schematic connections between the circuit elements of the first group as a first schematic region. In the example, the preprocessor 108 identifies an n^{th} group from the circuit elements and schematic connections between the circuit elements of the n^{th} group as an n^{th} schematic region, where n is an integer greater than one.

Further, in the example, the preprocessor 108 converts the first and second types of grammar into the syntax trees. The syntax trees are semantic representations of the first and second types of grammar without any of the syntax or formatting details, such as dots or parenthesis or functions, enabling exploration and manipulation of core data of concern. To illustrate, the core data includes identities, such as identifiers, of the circuit elements and schematic connections between the circuit elements. As an example, an identifier is one or more alphanumeric characters, such as a series of alphanumeric characters that distinguishes a circuit element of the schematic design from another circuit element of the schematic design.

Examples of the schematic connections between the circuit elements include hardware connections, which are physical connections via metal conductors and contextual connections, which are nonphysical and interactive connections. To illustrate, the contextual connections include electromagnetic connections or parasitic capacitances or parasitic coupling or stress effects or any other nonphysical interactions between the circuit elements. To further illustrate, between a first inductor and a second inductor, there is no hardware connection, such as a metal conductor, coupling the first inductor with the second inductor but an electromagnetic coupling between the first and second inductors when a current flows through the first inductor, or a current flows through the second inductor, or the currents flow through the first and second inductors. An example of the metal conductor includes a wire. In the further illustration, a change in an amount of current through the first inductor modifies an electromagnetic field surrounding the second inductor to modify an amount of current flowing via the second inductor and vice versa. The first and second inductors are not connected with each other via a physical connection or hardware connection, such as a metal conductor. As another further illustration, between a first capacitor and a second capacitor, there is a parasitic capacitance, which is not a capacitance of the first capacitor or the second capacitor. The parasitic capacitance is sometimes referred to herein as a stray capacitance. An example of the stress effect between a first circuit element of the schematic design and a second circuit element of the schematic design is when the first and second circuit elements are proximate with each other. To illustrate, when the first circuit element is close to the second circuit element to be within a predetermined range, the stress effect is created.

Further, in an operation 118, the preprocessor 108 inflates and builds, the normalized IR to flatten the hierarchical formats to output an intermediate representation of the schematic design. For example, the preprocessor 108 integrates multiple tree structures of the normalized intermediary representation into the intermediate representation. To illustrate, the preprocessor 108 identifies that the normalized IR includes a first tree structure, such as a first syntax tree, having a first circuit element, a second circuit element, a third circuit element, an additional third circuit element, and schematic connections between the first circuit element, the second circuit element, and the two third circuit elements. In the illustration, in the first tree structure, the first circuit element is connected via a first schematic connection to the second circuit element, via a second schematic connection to the third circuit element, and via a third schematic connection to the additional third circuit element.

In the illustration, an m^{th} circuit element and an additional m^{th} circuit element are of the same type, such as capacitors, or inductors, or transformers, or OR gates, or diodes, or a type of logic gate, where m is a positive integer. To further illustrate, the third circuit element is an AND gate and so is the additional third circuit element. In the illustration, the m^{th} circuit element is a first reference of the m^{th} circuit element and the additional m^{th} circuit element is a second reference of the m^{th} circuit element.

Also, in the illustration, the preprocessor 108 identifies that the normalized IR includes a second tree structure, such as a second syntax tree, having the third circuit element, a fourth circuit element, and a fifth circuit element, and schematic connections between the third, fourth, and fifth circuit elements. In the illustration, in the second tree structure, the third circuit element is connected via a fourth schematic connection to the fourth circuit element and is connected via a fifth schematic connection to the fifth circuit element. Further, in the illustration, the preprocessor 108 combines the first and second tree structures into a combined tree structure having the first circuit element, the second circuit element, the third circuit element, the additional third circuit element, the fourth circuit element, the fifth circuit element, and the first through fifth schematic connections.

Continuing with the illustration, the preprocessor 108 generates the combined tree structure having the circuit elements and the schematic connections of the first tree structure. In addition, the preprocessor 108 includes within the combined tree structure, the fourth schematic connection from the third circuit element to the fourth circuit element. Also, the preprocessor 108 includes within the combined tree structure, the fifth schematic connection from the third circuit element to the fifth circuit element. The preprocessor 108 includes within the combined tree structure, a sixth schematic connection from the additional third circuit element to an additional fourth circuit element. Also, the preprocessor 108 includes within the combined tree structure, a seventh schematic connection from the additional third circuit element to an additional fifth circuit element. In the example, the preprocessor 108 simplifies the first and second syntax trees to create an inflated version of the schematic design. As such, the inflated version is created by filling out each reference to a circuit element in the normalized IR.

The preprocessor 108 also executes an operation 120 of parsing, such as analyzing or traversing, the layout files 104 to create an intermediate representation of the layout design without creating multiple tree structures of the layout design. For example, the intermediate representation, such as a single tree structure, is inflated and built. As another example, the preprocessor 108, identifies from the layout files 104, layouts corresponding to the circuit elements of the schematic design and schematic connections between the layouts. To illustrate, the layout files 104 include a unique relationship, such as a one-to-one relationship or a link, between each circuit element of the schematic design and a respective one of the layouts of the layout design. To further illustrate, the layout files 104 include a unique relationship between a schematic of an OR gate in the schematic design and a layout of the same OR gate in the layout design. In the further illustration, the preprocessor 108 determines that the schematic and the layout are of the same OR gate upon determining that a series of alphanumeric characters assigned to the schematic in one of the schematic files 102 matches a series of alphanumeric characters assigned to the layout in one of the layout files 104. To further illustrate, the layout files 104 include a unique relationship between a schematic of a transistor in the schematic design and a layout of the same transistor in the layout design. In the further illustration, the preprocessor 108 determines that the schematic and the layout are of the same transistor upon determining that a series of alphanumeric characters assigned to the schematic in one of the schematic files 102 matches a series of alphanumeric characters assigned to the layout in one of the layout files 104. Also, in the example, after identifying the layouts, the preprocessor 108 identifies layout connections between the layouts as corresponding to the schematic connections between the circuit elements of the schematic design. To illustrate, the layout files 104 include a unique relationship, such as a one-to-one relationship or a link, between each layout connection of the layout design and a respective one of the schematic connections of the schematic design. To further illustrate, the layout files 104 include a unique relation between a schematic connection between an OR gate and an AND gate in the schematic design and a layout connection between the same OR gate and the same AND gate in the layout design. Illustrations of layout connections include vias, pin ins, pin outs, and metal traces.

Moreover, in the example, after identifying the layouts, the preprocessor 108 assigns the identifiers to the layouts based on the identifiers of the circuit elements and connections between the circuit elements. For example, the preprocessor 108 assigns the same ID to a layout as that assigned to a circuit element having the unique relationship with the layout. To further illustration, when a first inductor is connected to a first resistor and a second inductor is connected to a second resistor, the preprocessor 108 assigns a first ID, assigned to the first inductor, to a first layout of the first inductor. Also, the preprocessor 108 assigns a second ID, assigned to the second inductor, to a second layout of the second inductor. Moreover, upon identifying, from the schematic files 102 (FIG. 1A) that the first inductor is connected to the first resistor, the preprocessor 108 assigns a third ID, assigned to the first resistor, to a third layout of the first resistor. Also, upon identifying, from the schematic files 102 that the second inductor is connected to the second resistor, the preprocessor 108 assigns a fourth ID, assigned to the second resistor, to a fourth layout of the second resistor.

Further, in the example, to create the intermediate representation of the layout design, the preprocessor 108 includes, within the intermediate representation, a first layout of the layout design, a second layout of the layout design, a third layout of the layout design, and an additional third layout of the layout design. The preprocessor 108 includes, within the intermediate representation, a first layout connection between the first layout and the second layout, a second layout connection between the first layout and the third layout, and a third layout connection between the first layout and the additional third layout. Also, in the example, the preprocessor 108 includes, within the intermediate representation, a fifth layout connection between the third layout and a fourth layout and a sixth layout connection between the third layout and a fifth layout. Also in the example, the preprocessor 108 includes, within the intermediate representation, a sixth layout connection between the additional third layout and an additional fourth layout and a seventh layout connection between the additional third layout and an additional fifth layout.

In the example, an m^{th} layout and an additional m^{th} layout are of the same type, such as OR gates, or diodes, or a type of logic gate, where m is a positive integer. To further illustrate, the third layout is of an AND gate and the additional third layout is of another AND gate.

Examples of a layout of the layout design include a layout region, such as an npn region of a transistor, a pn region of a diode, a pnp region of a transistor, a source-gate-drain region of a transistor, a metal trace, a layout of different signal paths, a layout of an analog circuit element, a layout region between multiple circuit elements, a layout of a metal trace or connection between two transistors, a layout of an electromagnetic coupling or parasitic coupling or stress effects or stray capacitive coupling between two circuit elements, a layout region of a logic gate, and a layout region of a circuit element of the schematic design. An example of a layout connection includes a via between two layout regions. Another example of a layout connection includes a contextual connection, such as a stress effect, between two layout regions that are proximate to each other. To illustrate, the layout connection is a force that is applied by a first layout region on a second layout region when the two layout regions are or are not in physical contact with each other. In the illustration, the first layout region is located over, such as on top of, the second layout region. Also, in the illustration, the first layout region is proximate to the second layout region when the two regions are within a predetermined distance from each other. To further illustration, there is none or a number of layout regions between the first and second layout regions. A layout region is sometimes referred to herein as a layout component.

In an embodiment, an intermediate representation is sometimes referred to herein as an intermediary representation and these terms are used herein interchangeably.

FIG. 1B-1 is a diagram of an embodiment of multiple tree structures 122 and 124, and of an embodiment of an intermediate representation 126 of the schematic design. The tree structures 122 and 124 are an example of the normalized IR. The tree structure 122 includes a circuit A that is coupled via a schematic connection 128₁ to a device 1. The letter A of the circuit A is an example of a circuit ID A of a circuit element of the schematic design and the number 1 of the device 1 is also an example of a circuit ID of another circuit element of the schematic design. The tree structure 122 also includes a schematic connection 128₂ between the circuit A and a circuit B and a schematic connection 128₃ between the circuit A and an additional circuit B. The letter B of the circuit B is an example of a circuit ID of a circuit element of the schematic design and the words additional B of the additional circuit B is an example of a circuit ID of a circuit element of the schematic design.

Also, the tree structure 124 includes the circuit B that is coupled via a schematic connection 128₄ to a device 2 and is coupled via a schematic connection 128₅ to a device 3. The number 2 of the device 2 is an example of a circuit ID of a circuit element of the schematic design and the number 3 of the device 3 is an example of a circuit ID of a circuit element of the schematic design.

The intermediate representation 126 is formed by the preprocessor 108 (FIG. 1A) by integrating the tree structures 122 and 124. For example, the intermediate representation 126 of the schematic design includes the circuit elements of the tree structure 122 and schematic connections between the circuit elements of the tree structure 122. In addition, the intermediate representation 126 includes the devices 2 and 3 and the schematic connections 128₄ and 128₅. Also, the intermediate representation 126 includes the additional circuit B, an additional device 2, an additional device 3, a schematic connection 128₆ between the additional circuit B and the additional device 2, and a schematic connection 128₇ between the additional circuit B and the additional device 3. The words additional 2 of the additional device 2 is an example of a circuit ID of a circuit element of the schematic design and the words additional 3 of the additional device 3 is an example of a circuit ID of a circuit element of the schematic design. In the intermediate representation 126, each circuit element is sometimes referred to herein as a net or a node and each schematic connection is sometimes referred to herein as an edge. The circuit IDs A, B, additional B, 1, 2, 3, additional 2, and additional 3 are assigned by the preprocessor 108.

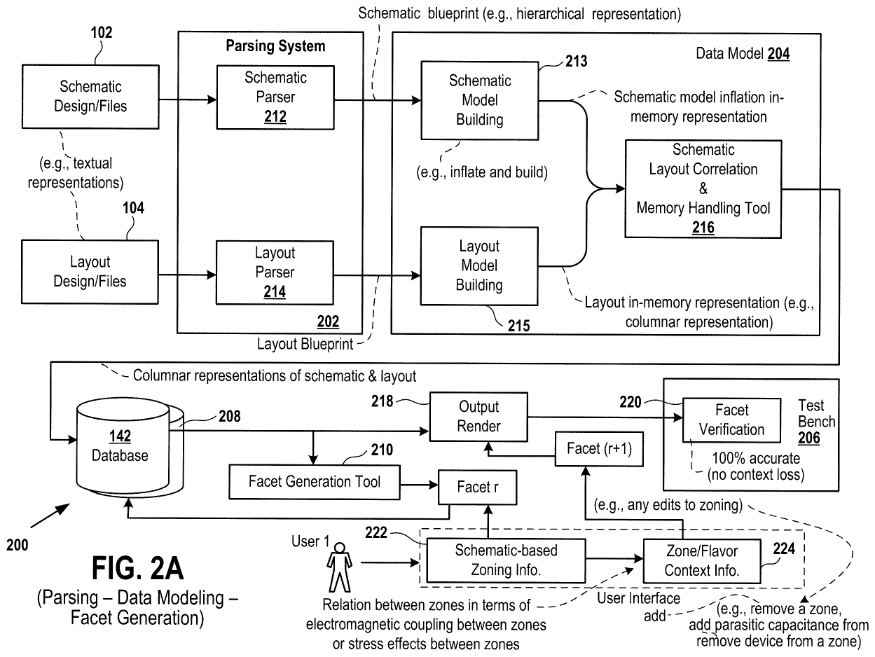

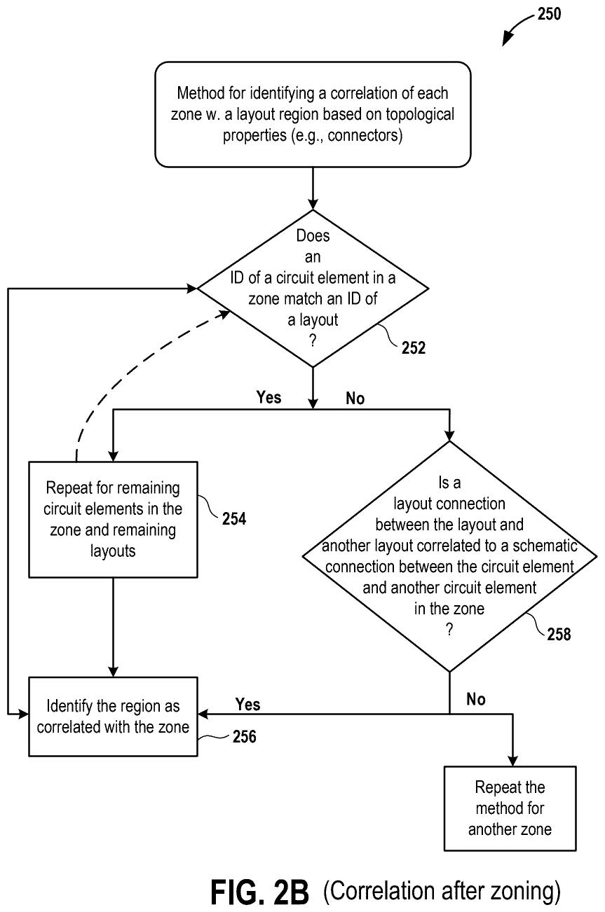

FIG. 1B-2 is a diagram of an embodiment of an intermediate representation 130 of the layout design. The intermediate representation 130 includes a layout region A, a layout component 1, a layout region B, an additional layout region B, a layout component 2, a layout component 3, and an additional layout component 2, and an additional layout component 3. Each of the layout region A, the layout component 1, the layout region B, the additional layout region B, the layout component 2, the layout component 3, and the additional layout component 2, and the additional layout component 3 is an example of a layout of the layout design. For example, the layout region A is a layout of the circuit A, the layout component 1 is a layout of the device 1, the layout region B is a layout of the circuit B, the additionally layout region B is a layout of the additional circuit B, the layout component 2 is the layout of the device 2, the layout component 3 is a layout of the device 3, the additional layout component 2 is a layout of the additional device 2, and the additional layout component 3 is a layout of the additional device 3.

The layout region A is connected to the layout component 1 via a layout connection 132₁, is connected to the layout region B via a layout connection 132₂, and is connected to the additional layout region B via a layout connection 132₃. The layout region B is connected to the layout component 2 via a layout connection 132₄ and is connected to the layout component 3 via a layout connection 132₅. The additional layout region B is connected to the additional layout component 2 via a layout connection 132₆ and is connected to the additional layout component 3 via a layout connection 132₇.

FIG. 1C-1 is a diagram of an embodiment of a system 134 to illustrate facet generation. FIG. 1C-2 is a diagram of an embodiment of an arrow columnar format 136, such as apache arrow, that is generated from the intermediate representation of the schematic design. FIG. 1C-3 is a diagram of an embodiment of an arrow columnar format 138, such as apache arrow, that is generated from the intermediate representation of the layout design. The arrow columnar formats 136 and 138 that are generated based on the blueprint schematic provide a unified data model. The unified data model is a prerequisite for faster searching.

The system 134 includes a computer 140, a memory device 141, a database 142, and a processor 144. Examples of a computer, as used herein, include a tablet, a desktop computer, a laptop computer, and a smart phone. The processor 144 is a component of one or more servers of a server system, which include the memory device 141. The processor 144 is coupled to the memory device 141, and is coupled to the computer 140 via a computer network 167. Examples of the computer network 167 include the Internet or an Intranet or a combination thereof. The database 142 is stored in the memory device 141.

The processor 144 executes an operation 146 of converting the intermediate representation of the schematic design to an arrow columnar format, which is sometimes referred to herein as a columnar structure, of the schematic design. For example, the intermediate representation 126 (FIG. 1B-1) is converted into the arrow columnar format 136. To illustrate, with reference to FIG. 1C-2, the processor 144 generates a table including multiple columns, such as a column 148₁ and a column 148₂, and multiple rows, such as a row 150₁, a row 150₂, a row 150₃, and a row 150₄ to form cells. In the illustration, at a cell formed by an intersection of the column 148₁ and the row 150₁, the processor 144 generates a designation of a unique circuit ID, such as a header, which is an ID of a circuit element of the intermediate representation of the schematic design. At a cell formed by an intersection of the column 148₂ and the row 150₁, the processor 144 stores a circuit ID A of the circuit A, a circuit ID B of the circuit B, and an additional circuit ID B of the additional circuit B. The circuit ID A is indicated as A, the circuit ID B is indicated as B, and the circuit ID additional B is indicated as additional B in FIG. 1C-2. In the illustration, a circuit ID in unique to each circuit element of the schematic design and distinguishes the circuit element of the intermediate representation of the schematic design from another circuit element of the intermediate representation of the schematic design.

Also, in the illustration, at a cell formed by an intersection of the column 148₁ and the row 150₂, the processor 144 generates a designation of a unique device ID. At a cell formed by an intersection of the column 148₂ and the row 150₂, the processor 144 stores the ID 1 of the device 1, the ID 2 of the device 2, the ID 3 of the device 3, the ID additional 2 of the additional device 2, and the ID additional 3 of the additional device 3. In the illustration, a device identifier in unique to each device of the intermediate representation of the schematic design and distinguishes the device of the intermediate representation of the schematic design from another device of the intermediate representation of the schematic design. The processor 144 assigns the IDs A, B, additional B, 1, 2, 3, additional 2, and additional 3 in the illustration.

Further, in the illustration, at a cell formed by an intersection of the column 148₁ and the row 150₃, the processor 144 generates a designation of a schematic connection ID, which is an ID of any of the schematic connections, such as contextual connections, described herein. At a cell formed by an intersection of the column 148₂ and the row 150₃, the processor 144 generates a circuit connection ID [{Circuit A}, {Device 1}] indicating a schematic connection between the circuit A and the device 1, a circuit connection ID [{Circuit A}, {Circuit B}] indicating a schematic connection between the circuit A and the circuit B, a circuit connection ID [{Circuit A}, {Additional device B}] indicating a schematic connection between the circuit A and the additional circuit B. Also, in the cell formed by an intersection of the column 148₂ and the row 150₃, the processor 144 generates a circuit connection ID [{Circuit B}, {Device 2}] indicating a schematic connection between the circuit B and the device 2, a circuit connection ID [{Circuit B}, {Device 3}] indicating a schematic connection between the circuit B and the device 3, a circuit connection ID [{Additional circuit B}, {Additional device 2}] indicating a schematic connection between the additional circuit B and the additional device 2, and a circuit connection ID [{Additional circuit B}, {Additional device 3}] indicating a schematic connection between the additional circuit B and the additional device 3. A circuit connection is sometimes referred to herein as a schematic connection.

Continuing with the illustration, the processor 144 generates a designation of a circuit element type in a cell at an intersection of the row 150₄ and the column 148₁. It should be noted that a first type of circuit element is different from a second type of circuit element in structure and function. For example, an AND gate has a different structure, such as a first set of circuit elements, than a structure including a second set of circuit elements of an OR gate. The structure includes of the AND gate has different schematic connections between the first set of circuit elements than schematic connections between the second set of circuit elements. The AND gate also has different functions than functions of the OR gate. As another example, a capacitor has a different schematic than a schematic of a resistor and different functions than functions of the resistor. Examples of the designation of the circuit element type include a switch, a voltage source, a ground potential, a multiplexer, a demultiplexer, a processor, a memory device, an interconnect, a clock source, a digital signal source, an RF signal source, a battery, a transistor, a diode, a resistor, a transformer, an inductor, a capacitor, an AND gate, an OR gate, a NOR gate, and a NAND gate. In the illustration, the processor 144 indicates, at an intersection of the row 150₄ and the column 148₂, that the circuit A is an inverter, the device 1 is a transistor, the circuit B is an AND gate, the additional circuit B is an additional AND gate, the device 2 is an OR gate, the device 3 is another OR gate, the additional device 2 is an additional OR gate, and the additional device 3 is an additional OR gate.

Referring back to FIG. 1C-1, the processor 144 executes an operation 152 of converting the intermediate representation of the layout design into an arrow columnar format of the layout design. For example, the intermediate representation 130 (FIG. 1B-2) is converted into the arrow columnar format 138. To illustrate, with reference to FIG. 1C-3, the processor 144 generates a table including multiple columns, such as a column 152₁ and a column 152₂, and multiple rows, such as a row 154₁, a row 154₂, a row 154₃, a row 154₄, and a row 154₅ to form cells. In the illustration, at a cell formed by an intersection of the column 154₁ and the row 156₁, the processor 144 generates a designation of a unique layout region ID. At a cell formed by an intersection of the column 152₂ and the row 154₁, the processor 144 stores the ID A of the layout region A, the ID B of the layout region B, and the ID additional B of the layout region B. In the illustration, an ID is unique to each layout region of the intermediate representation of the layout design and distinguishes the layout region from another layout region of the intermediate representation of the layout design.

The processor 144 assigns the IDs A, B, additional B, 1, 2, 3, additional 2, and additional 3 in the illustration. For example, based on the correspondences between the layouts of the layout design and the circuit elements of the intermediate representation of the schematic design received from the preprocessor 108, the processor 144 assigns the same ID to a layout of the intermediate representation of the layout design as that assigned to a corresponding circuit element of the intermediate representation of the schematic design. To further illustrate, in response to receiving an indication from the preprocessor 108 that a first layout of the layout design corresponds to a first circuit element of the schematic design and a second layout corresponds to a second circuit element of the layout design, the processor 144 assigns the identifier A to the first layout and the first circuit element and the identifier B to the second layout and the second circuit element.

Also, in the illustration, at a cell formed by an intersection of the column 152₁ and the row 154₂, the processor 144 generates a designation of a unique layout component ID. At a cell formed by an intersection of the column 150₂ and the row 154₂, the processor 144 stores the ID 1 of the layout component 1, the ID 2 of the layout component 2, the ID 3 of the layout component 3, the ID additional 2 of the additional layout component 2, and the ID additional 3 of the additional layout component 3. In the illustration, a layout component identifier in unique to each layout component of the intermediate representation of the layout design and distinguishes the layout component from another layout component of the intermediate representation of the layout design.

Further, in the illustration, at a cell formed by an intersection of the column 152₁ and the row 154₃, the processor 144 generates a designation of a layout connection ID, which is an ID of any of the layout connections, such as contextual connections, described herein. At a cell formed by an intersection of the column 152₂ and the row 154₃, the processor 144 generates a layout connection ID [{region A}, {compt 1}] indicating a layout connection between the layout region A and the layout component 1, a layout connection ID [{region A}, {region B}] indicating a layout connection between the layout region A and the layout region B, a layout connection ID [{region A}, {add region B}] indicating a layout connection between the layout region A and the additional layout region B. Also, in the cell formed by an intersection of the column 152₂ and the row 154₃, the processor 144 generates a layout connection ID [{region B}, {compt 2}] indicating a layout connection between the layout region B and the layout component 2, a layout connection ID [{region B}, {compt 3}] indicating a layout connection between the layout region B and the layout component 3, a layout connection ID [{add region B}, {add compt 2}] indicating a layout connection between the additional layout region B and the additional layout component 2, and a layout connection ID [{add region B}, {add compt 3}] indicating a schematic connection between the additional layout region B and the additional layout component 3. It should be noted that add is short for additional and compt is short for component.

In the illustration, the processor 144 correlates each layout connection with a respective schematic connection and stores the correlations between the layout and schematic connections in the database 142. For example, the processor 144 correlates the layout connection having the ID [{region A}, {compt 1}] with the schematic connection having the ID [{Circuit A}, {Device 1}], the layout connection having the ID [{region A}, {region B}] with the schematic connection having the ID [{Circuit A}, {Circuit B}], the layout connection having the ID [{region A}, {add region B}] with the schematic connection having the ID [{Circuit A}, {Additional circuit B}], the layout connection having the ID [{region B}, {compt 2}] with the schematic connection having the ID [{Circuit B}, {Device 2} ], the layout connection having the ID [{region B}, {compt 3}] with the schematic connection having the ID [{Circuit B}, {Device 3}], the layout connection having the ID [{add region B}, {add compt 2}] with the schematic connection having the ID [{Additional circuit B}, {Additional device 2}], and the layout connection having the ID [{add region B} , {add compt 3}] with the schematic connection having the ID [{Additional circuit B}, {Additional device 3} ].

In the illustration, the layout connection correlates to the respective schematic connection when the processor 144 determines that IDs of circuit elements connected to each other via the schematic connection match IDs of layout connected to each other via the layout connection. To further illustrate, the layout connection having the ID [{region A}, {compt 1}] correlates to the schematic connection having the ID [{Circuit A}, {Device 1}] when the processor 144 determines that IDs of the layout region A and the circuit A match and IDs of the layout component 1 and the device 1 match.

Continuing with the illustration, the processor 144 generates a designation of a layout type in a cell at an intersection of the column 152₁ and the row 154₄. It should be noted that a first type of layout is different from a second type of layout in structure and function. For example, an AND gate has a different structure, such as a first set of layouts, than a structure including a second set of layouts of an OR gate. The structure of the AND gate has different layout connections between the first set of layouts than layout connections between the second set of layouts. The AND gate also has different functions than functions of the OR gate. As another example, a capacitor has a different layout than a layout of a resistor and different functions than functions of the resistor. Examples of the designation of the layout type include a switch, a voltage source, a ground potential, a multiplexer, a demultiplexer, a processor, a memory device, an interconnect, a clock source, a digital signal source, an RF signal source, a battery, a transistor, a diode, a resistor, a transformer, an inductor, a capacitor, an AND gate, an OR gate, a NOR gate, and a NAND gate. In the illustration, the processor 144 indicates, at an intersection of the row 154₄ and the column 152₂, that the layout region A is an inverter, the layout component 1 is a transistor, the layout region B is an AND gate, the additional layout region B is an additional AND gate, the layout component 2 is an OR gate, the layout component 3 is another OR gate, the additional layout component 2 is an additional OR gate, and the additional layout component 3 is an additional OR gate.

As another example, an amplifier has a different structure, such as a first set of layouts, than a structure including a second set of layouts of a comparator. The structure of the amplifier has different layout connections between the first set of layouts than layout connections between the second set of layouts. The amplifier also has different functions than functions of the comparator. Examples of the designation of the layout type include a comparator, an amplifier, a clock generator, and a voltage reference circuit. In the illustration, the processor 144 indicates, at an intersection of the row 154₄ and the column 152₂, that the layout region A is a voltage reference circuit, the layout component 1 is a clock generator, the layout region B is an amplifier, the additional layout region B is an additional amplifier, the layout component 2 is a comparator, the layout component 3 is another comparator, the additional layout component 2 is an additional comparator, and the additional layout component 3 is an additional comparator.

Referring back to FIG. 1C-1, the processor 144 executes an operation 157 of correlating each circuit element of the schematic design with a respective layout of the layout design. For example, based on the arrow columnar format of the schematic design and the arrow columnar format of the layout design, the processor 144 correlates a circuit element of the schematic design and a layout of the layout design based on an ID of the circuit element and an ID of the layout design. To illustrate, in response to determining that a first circuit element of the schematic design is assigned the ID A and a first layout of the layout design is also assigned the ID A, the processor 144 correlates the first layout with the first circuit element. Also, in the illustration, in response to determining that a second circuit element of the schematic design is assigned the ID B and a second layout of the layout design is also assigned the ID B, the processor 144 correlates the second layout with the second circuit element. After executing the operation 157 of correlating, the processor 144 stores the arrow columnar formats of the schematic and layout designs and the correlations between the schematic design and the layout design in the database 142. The arrow columnar formats 136 and 138 provide compressed or columnar data representations. For example, blank memory locations within the memory device 141 are occupied by the arrow columnar formats of the schematic and layout designs. The arrow columnar formats 136 and 138 facilitates faster access and faster searching by the processor 144 of the schematic and layout designs and the correlations between the schematic design and the layout design from the database 142 compared to when the arrow columnar formats 136 and 138 are not used. As such, speed of access of data stored in the memory device 141 is increased.

A user 1 uses the computer 140 to access the schematic design from the database 142. For example, the user 1 selects one or more buttons on an input device, such as a keyboard 163 or a mouse 165 or a combination thereof. In response to receiving the selection, a processor of the computer 140 generates a request for accessing the schematic design stored in the arrow columnar format from the database 142 and sends the request via the computer network 167 to the processor 144. Upon receiving the request, the processor 144 accesses the arrow columnar format of the schematic design from the database 142 and displays the schematic design based on the arrow columnar format on a display device 169 of the computer 140. To illustrate, the processor 144 identifies the circuit elements of the circuit design from the arrow columnar format of the schematic design and identifies the schematic connections between the circuit elements from the arrow columnar format. The processor 144 generates the schematic design, such as a circuit design, having the circuit elements and the schematic connections for display of the circuit elements and the schematic connections. Examples of the display device 169 include a plasma display device and a light emitting diode display device. The computer 140 is an example of an output device.

Moreover, upon viewing the display of the schematic design on the display device 169, the user 1 uses the input device to identify zones 158, such as schematic regions, within the schematic design. For example, the user uses the input device to draw a first shape to encompass a first set of the circuit elements of the schematic design and schematic connections between the circuit elements to identify a first zone. Further, in the example, the user 1 uses the input device to draw a second shape to encompass a second set of the circuit elements of the schematic design and schematic connections between the circuit elements to identify a second zone. Illustrations of a shape, as used herein, include a polygon, a rectangle, the square, a circle, and an oval.

The processor of the computer 140 receives the zones 158 selected via the input device by the user 1 and sends the zones 158 via the computer network 167 to the processor 144. The processor 144 executes a facet generation and simulation operation 160 to generate one or more facets from the zones 158 and to simulate the one or more facets. For example, based on each of the zones 158, a corresponding one of the one or more facets is generated by the processor 144. To illustrate, when a first zone includes a first set of circuit elements and first set of schematic connections between the first set of circuit elements, the processor 144 identifies, from the arrow columnar formats of the schematic design and the layout design and the correlations between each of the circuit elements of the first set and a respective one of layouts of a first set, the first set of layouts correlating to the first set of circuit elements. In the illustration, the processor 144 identifies layout connections between the first set of layouts based on correlations, from the database 142, between each of the layout connections and a respective one of schematic connections between the first set of circuit elements. In the illustration, the processor 144 identifies the first set of layouts based on the IDs assigned to the circuit elements of the first set. To further illustrate, in response to identifying, from the arrow columnar format of the schematic design, that a first circuit element of the first set has the ID A, the processor 144 identifies from the arrow columnar format of the layout design a first layout having the ID A as correlating to the first circuit element. In the further illustration, in response to identifying, from the arrow columnar format of the schematic design, that a second circuit element of the first set has the ID B, the processor 144 identifies from the arrow columnar format of the layout design a second layout having the ID B as correlating to the second circuit element. In addition, in the further illustration, the processor 144 identifies, from the arrow columnar formats of the schematic design and the layout design and the correlations between a schematic connection of the first circuit element with the second circuit element and a layout connection of the first layout with the second layout, the layout connection between the first and second layouts for faster searching. As such, in the further illustration, the unified data model, such as the arrow columnar format 136 or 138, facilitates faster searching of the layout connection based on the schematic connection according to the correlations between the schematic connection and the layout connection.

In the illustration, when a second zone includes a second set of circuit elements and a second set of connections between the second set of circuit elements, the processor 144 identifies, from the arrow columnar formats of the schematic design and the layout design and the correlations between each of the circuit elements of the second set and a respective one of layouts of a second set, the second set of layouts correlating to the second set of circuit elements. In the illustration, the processor 144 identifies layout connections between the second set of layouts based on correlations, from the database 142, between each of the layout connections and a respective one of schematic connections between the second set of circuit elements. In the illustration, the processor 144 identifies the second set of layouts based on the IDs assigned to the circuit elements of the second set. To further illustrate, in response to identifying, from the arrow columnar format of the schematic design, that a third circuit element of the second set has the ID 1, the processor 144 identifies from the arrow columnar format of the layout design a third layout having the ID 1 as correlating to the third circuit element. In the further illustration, in response to identifying, from the arrow columnar format of the schematic design, that a fourth circuit element of the second set has the ID 2, the processor 144 identifies from the arrow columnar format of the layout design a fourth layout having the ID 2 as correlating to the fourth circuit element. In addition, in the further illustration, the processor 144 identifies, from the arrow columnar formats of the schematic design and the layout design and the correlations between a schematic connection of the third circuit element with the fourth circuit element and a layout connection of the third layout with the fourth layout, the layout connection between the third and fourth layouts.

Continuing with the illustration, the processor 144 generates a first facet including the first set of layouts and the layout connections between the layouts of the first set and generates a second facet including the second set of layouts and the layout connections between the layouts of the second set. The processor 144 provides the first and second facets to a simulation tool, such as a facet verification tool, of a test bench to test the first and second facets to execute the operation 160. An example of a tool, as used herein, includes an ASIC or a PLD or a computer software program executed by a processor, such as the processor 144, described herein. The processor 144 executes the simulation tool to test the first and second facets to output test results 162. Examples of the test results 162 include whether a layout is functional or meets predetermined dimensions and/or a contextual connection of the facet r is functional. To illustrate, the simulation tool determines that a predetermined amount of change in a current flowing in a first layout of the facet r achieves a predetermined amount of change in a current flowing in a second layout of the facet r. The first and second layouts are coupled to each other via a contextual connection. Upon determining that the predetermined amount of change in the current in the first layout achieves the predetermined amount of change in the current in the second layout of the facet r, the simulation tool determines that the first and second layouts and the contextual connection are functional. The test results 162 are sent from the processor 144 to the computer 140 via the computer network 167 to display the test results 162 on the display device 169.

The unified data model is a prerequisite for faster searching. For example, the processor 144 accesses the arrow columnar formats 136 and 138 to determine a layout connection corresponding to a schematic connection. The layout connection is of the layout design and the schematic connection is of the schematic design. To illustrate, in response to accessing the circuit connection ID [{Circuit A}, {Device 1}], the processor 144 accesses a corresponding layout connection having the layout connection ID [{region A}, {compt 1}] based on the circuit connection ID. To further illustrate, the processor 144 determines that the region A corresponds to, such as has a unique relationship with, the circuit A based on a match between the assigned IDs A to the region A and the circuit A. The processor 144 determines that the component 1 corresponds to, such as has a unique relationship with, the device 1 based on a match between the assigned IDs 1 to the component 1 and the device 1. Further, in response to determining that the schematic connection, having the ID [{Circuit A}, {Device 1}], identifying the schematic connection between the circuit A and the device 1 exists in the database 142, the processor 144 determines that the layout connection having the ID [{region A}, {compt 1}] identifying the layout connection between the region A and the component 1 exists in the database 142.

Also, the processor 144 executes parallel edits on information within the arrow columnar formats 136 and 138. For example, the processor 144 edits, such as modifies or changes, circuit IDs in the row 150₁, or device IDs in the row 150₂, or circuit connection IDs in the row 150₃, or circuit element types in the row 150₄, or layout region IDs in the row 154₁, or layout component IDs in the row 154₂, or layout connection IDs in the row 154₃, or layout types in the row 154₄, or a combination thereof, simultaneously. To illustrate, in response to receiving an input indicating one or more selections, from the user, of the one or more buttons of the input device for changing the circuit IDs, in the row 150_{1,} from A to A1 and B to B1, the processor 144 changes, in the rows 150₂, 150₃, 150₄, 154₁, 154₂, 154₃, and 154₄, the circuit ID A to A1, the circuit ID B to B1, the layout region ID A to A1, and the layout region ID B to B1 at the same time to achieve row level database automated parallelism. As another illustration, in response receiving an input indicating one or more selections, from the user, of the one or more buttons of the input device for changing the circuit ID A to A1, the processor 144 simultaneously, such as at the same time or in parallel, modifies the circuit ID A to A1 in the rows 150₁ through 150₄, and modifies the layout region ID A to A1 in the rows 154₁ through 154₄.

In one embodiment, instead of the database 142, multiple databases are used. For example, a first database stores the arrow columnar format of the schematic design, a second database stores the arrow columnar format of the layout design, and either the first or second database stores the correlations between the schematic design and the layout design. The correlations between the schematic design and the layout design include the correlations between circuit elements of the schematic design and layouts of the layout design, and the correlations between schematic connections of the schematic design and layout connections of the layout design.

In one embodiment, the operations described herein as being performed by the preprocessor 108 (FIG. 1A) and the processor 144 are performed by the processor 144 or by more than two processors.

In one embodiment, the functions described herein as being performed by the preprocessor 108 are performed by the processor 144 or a combination of the preprocessor 108 and the processor 144.

In an embodiment, the functions described herein as being performed by the processor 144 are performed by the preprocessor 108 or a combination of the preprocessor 108 and the processor 144.

In an embodiment, the terms correlate and correspond or the terms correlating and corresponding are used herein interchangeably. To illustrate, when a layout correlates to a circuit element, the layout corresponds to the circuit element. As another further illustration, when a layout connection correlates to a schematic connection, the layout connection corresponds to the schematic connection.

In an embodiment, the preprocessor 108 and the processor 144 are processors of a server system that is coupled to the computer 140 via the computer network 167. For example, any communication between the processor of the computer 140 and the processor 144 or the preprocessor 108 occur via the computer network 167.

In an embodiment, the functions described herein as being performed by the processor of the computer 140 are performed under the direction, such as in response to receiving instructions or commands from, one or more of the preprocessor 108 and the processor 144.

In an embodiment, the functions described herein as being performed by the processor of the computer 140 are performed by the processor 144 (FIG. 1C-1).

In an embodiment, some of the functions described herein as being performed by the processor of the computer 140 are performed by the processor of the computer 140 and remaining of the functions are performed by the processor 144.

In one embodiment, instead of the memory device 141, multiple memory devices, such as the memory devices 110 and 141, of the server system are used.

In an embodiment, instead of the memory device 141, the memory device 110 (FIG. 1A) is used or vice versa.

In an embodiment, each row, such as the row 150₁, 150₂, 150₃, 150₄, 154₁, 154₂, 154₃, or 154₄ is sometimes referred to herein as a column and each column, such as the column 148₁, 148₂, 152₁, or 152₂ is sometimes referred to herein as a row.

FIG. 2A is a diagram of an embodiment of a system 200 to illustrate generation of a facet r, where r is a positive integer. The system 200 includes the schematic files 102, the layout files 104, a parsing system 202, a data model 204, a testbench 206, the database 142 and a database 208, a facet generation tool 210, and the facet r. The parsing system 202 includes a schematic parser 212 and a layout parser 214. Examples of a parser, as used herein, include a processor, an ASIC, a PLD, and a computer software program. To illustrate, each parser 212 and 214 is a computer software program executed by the preprocessor 108 (FIG. 1A).

Examples of a model, as used herein, include a processor, an ASIC, a PLD, and a computer software program. To illustrate, the data model 204 is a computer software program executed by the processor 144 (FIG. 1C-1). As an example, the facet generation tool 210 is an ASIC or a PLD or a computer software program executed by the processor 144. Examples of a testbench, as used herein, include a processor, an ASIC, a PLD, and a computer software program. To illustrate, the testbench 206 is a computer software program executed by the processor 144.

The data model 204 is coupled to the schematic parser 212 and to the layout parser 214. Also, the data model 204 is coupled to the databases 142 and 208. The facet generation tool 210 is coupled to the databases 142 and 208 and to the testbench 206 via an output render tool 218.

The data model 204 includes a schematic model building tool 213 and a layout model building tool 215. Also, the data model 204 includes a schematic-layout correlation and memory handling tool (SLCMHT) 216. The tools 213 and 215 are coupled to the SLCMHT 216. The SLCMHT 216 is coupled to the databases 142 and 208.

The system 200 includes the output render tool 218. The output render tool 218 is coupled to the facet generation tool 210 and to a facet verification tool 220 of the test bench 206. The testbench 206 includes the facet verification tool 220. The facet verification tool 220 is an example of the simulation tool.

The schematic parser 212 receives the schematic files 102 and applies the operation 116 (FIG. 1A) of parsing the schematic files 102 to generate the normalized IR of the schematic design and to identify the schematic regions within the schematic design. The schematic parser 212 also executes the operation 118 (FIG. 1A-1) of inflating and building the normalized IR to output the intermediate representation of the schematic design. The schematic parser 212 provides the intermediate representation of the schematic design and the schematic regions of the schematic design to the schematic model building tool 213. The schematic model building tool 213 executes the operation 146 (FIG. 1C-1) of converting the intermediate representation of the schematic design to the arrow columnar format of the schematic design. The schematic model building tool 213 provides the arrow columnar format of the schematic design to the SLCMHT 216.

Also, the layout parser 214 receives the layout files 104 and applies the operation 120 (FIG. 1A) of parsing the layout files 104 to generate the intermediate representation of the layout design. The layout parser 214 provides the intermediate representation of the layout design to the layout model building tool 215. The layout model building tool 215 executes the operation 152 (FIG. 1C-1) of converting the intermediate representation of the layout design to output the arrow columnar format of the layout design. The layout model building tool 215 provides the arrow columnar format of the layout design to the SLCMHT 216.

The SLCMHT 216 executes the operation 157 (FIG. 1C-1) of correlating each circuit element of the schematic design with a respective layout of the layout design, and stores the arrow columnar formats of the schematic and layout designs and the correlations between the circuit elements and the layouts in one or more of the databases 142 and 208. For example, the SLCMHT 216 stores the arrow columnar format of the schematic design in the database 142 and the arrow columnar format of the layout design in the database 208. Also, in the example, the correlations between the circuit elements of the schematic design and the layouts of the layout design are stored in either the database 142 or the database 208.

The user 1 provides schematic-based zoning information 222, such as the zones 158, to the processor of the computer 140 (FIG. 1C-1) and in response to receiving the selection of the zones 158, such as including a first set including a zone or two zones or three zones or any other number of zones, generates the facet r from the zones 158. For example, the user 1 selects one or more buttons on the input device that is coupled to the processor of the computer 140 to select the zones 158 from the schematic design that is displayed on the display device 169. In the example, the schematic design includes a greater number of zones than a number of the zones 158. Continuing with the example, the processor 144 executes the facet generation and simulation tool 160 (FIG. 1C-1) to generate the facet r including one or more layouts corresponding to the zones 158. To illustrate, the facet r includes multiple layouts corresponding to multiple zones of a first set selected by the user 1 and the layouts are connected to each other via the contextual connections between the zones of the first set. The facet r also includes contextual connections. The zones 158 used to generate the facet r provide a first verification scenario.

In response to the generation of the facet r, the facet generation tool 210 provides the facet r to the output render tool 218. In response to receiving the facet r, the output render tool 218 provides the facet r to the facet verification tool 222 to test the facet r to output the test results 162, such as including a first set of test results.

The user 1 further provides zone or flavor or context (zone/flavor/context) information 224, such as modifications to the zones 158, to the processor of the computer 140. For example, the user 1 selects one or more buttons on the input device that is coupled to the processor of the computer 140 to modify, such as add zones to or remove zones from, the zones 158 within the schematic design that is displayed on the display device 169. To illustrate, the user 1 changes one or more contextual connections between the zones 158 to output a second set of zones, such as one zone or two zones or three zones or any other number of zones. To further illustrate, the user 1 selects one or more buttons on the input device to add a parasitic capacitance between the zones 158 to output the zones of the second set. As another illustration, the user 1 removes one or more circuit elements from the zones 158 to output the zones of the second set.

Integrity of the schematic design is maintained by the processor 144 when the user 1 modifies the zones 158. For example, with reference to the preceding illustration, after the zones 158 are modified to output the second set of zones, the processor 144 checks integrity of the second set of zones. To illustrate, the processor 144 sends an input parameter signal, such as a current signal, from an input of a circuit element of a first one of the zones of the second set via one or more connections to a second one of the zones of the second set to determine whether the input parameter signal is provided as an output from the second one of the zones. The processor 144 determines the input parameter signal is received as the output from the second one of the zones to determine that the integrity of the first one of the zones and the second one of the zones and the connections therebetween is preserved in the first and second sets. The integrity is preserved when there is no open circuit or short circuit in the first and second sets. In the illustration, the processor 144 determines that interactions between the first one of the zones and the second one of the zones are electrically valid. In the illustration, the first one of the zones of the first and second sets have the same circuit elements and the same connections. The second one of the zones of the first and second sets have the same circuit elements and the same connections. Also, in the illustration, the connections, such as contextual connections, between the first and second ones of the zones of the first and second sets are the same. In the illustration, the first one of the zones and the second one of the zones and the connections between the zones remain after a zone is removed from the first set to form the second set or after a zone is added to the first set to form the second set. The integrity preserves an accuracy of simulation of the facet r and a facet (r+1) generated, by the processor 144, from the second set of zones.

In response to receiving the selection of the zone/flavor/context information 224, such as the second set of zones, from the schematic design, the facet generation tool 210 generates the facet (r+1) from the second set of zones. For example, the processor 144 executes the facet generation and simulation tool 160 to generate the facet (r+1) including one or more layouts corresponding to the second set of zones. To illustrate, the facet (r+1) includes multiple layouts corresponding to the zones of the second set selected by the user 1 from the schematic design and the layouts are connected to each other via the same layout connections, such as contextual connections, as those between the zones of the first set. In the example, at least one zone of the second set is different from at least one zone of the first set that is used to generate the facet r. The second set of zones used to generate the facet (r+1) provide a second verification scenario.

Because the facet r has the contextual connections of the zones 158 and the facet (r+1) has the same contextual connections, there is a high amount of accuracy, such as 100%, in testing the facets r and (r+1). To illustrate, there is no obfuscation, such as black boxing or grey boxing, by the processor 144 (FIG. 1C-1) of any of the contextual connections of the facet r or the facet (r+1). When the obfuscation occurs, there is no testing of the contextual connections and therefore, the test does not achieve the high amount of accuracy. As such, the obfuscation reduces accuracy during testing of the facet r. By preserving the contextual connections between the layouts of the facet r and the contextual connections between the layouts of the facet (r+1), the high amount of accuracy is achieved.

The facet generation tool 210 provides the facet (r+1) to the output render tool 218. In response to receiving the facet (r+1), the output render tool 218 provides the facet (r+1) to the facet verification tool 222 to test the facet (r+1) to output the test results 162, such as including a second set of test results.

In one embodiment, the correlations between the circuit elements of the schematic design and the layouts of the layout design are stored in a database other than the databases 142 and 208.

In an embodiment, the user 1 uses the input device to select both the first and second sets of zones from the schematic design. The first set of zones and the second set of zones are transferred from the processor of the computer 140 to the facet generation tool 210. The facet generation tool 210 generates the facet r from the first set of zones and the facet (r+1) from the second set of zones simultaneously, such as at the same time or within a pre-determined time period. The facet generation tool 210 sends both the facets r and (r+1) simultaneously, such as at the same time or within a pre-determined time period, to the facet verification tool 220. The facet verification tool 220 tests the facets r and (r+1) simultaneously, such as at the same time or within a pre-determined time period.

In one embodiment, the operation 157 includes correlating each schematic connection of the schematic design with a respective layout connection of the layout design, and storing the correlations between the schematic connections and the layout connections in one or more of the databases 142 and 208. An example of correlating each schematic connection of the schematic design with a respective layout connection of the layout design is described above with reference to FIG. 1C-3.

FIG. 2B is a flowchart of an embodiment of a method 250 for identifying a correlation between a zone selected from the schematic design and a layout, such as a layout design portion, from the layout design. The method 250 is executed by the processor 144 (FIG. 1C-1). The method 250 is executed in response to receiving a selection of one of the zones 158 (FIG. 1C-1), such as a first zone, from the user 1 via the input device. In response receiving the selection of the first zone, the processor 144 accesses the arrow columnar formats of the schematic and layout designs and the correlations between the schematic and layout designs from one or more of the databases 142 and 208 (FIG. 2A) to determine, in an operation 252, whether an ID of a first circuit element from multiple circuit elements in the first zone matches an ID of a first layout from multiple layouts correlating to the circuit elements of the first zone. The ID of the first circuit element is stored in the arrow columnar format of the schematic design and the ID of the first layout is stored in the arrow columnar format of the layout design.

In response to determining that the IDs of the first circuit element and the first layout match, the processor 144 executes an operation 254 of the method 250 to determine whether remaining IDs of remaining ones of the circuit elements in the first zone match remaining IDs of remaining ones of the layouts correlating to the remaining ones of the circuit elements of the first zone. The remaining ones of the circuit elements are referred to as remaining circuit elements and the remaining ones of the layouts are referred to as remaining layouts. The remaining IDs of the remaining circuit elements are stored in the arrow columnar format of the schematic design and the remaining IDs of the remaining layouts are stored in the arrow columnar format of the layout design.

Upon determining that the remaining IDs of the remaining layouts correlating to the remaining circuit elements of the first zone match the remaining IDs of the remaining circuit elements of the first zone, the processor 144 identifies, in an operation 256 of the method 250, the first layout and the remaining layouts as being correlated with the first zone. Also, in the operation 256, the processor 144 determines that the first layout and the remaining layouts belong to the layout design portion that correlates to the first zone. On the other hand, in response to determining that one of the remaining IDs of one of the remaining circuit elements in the first zone does not match one of the remaining IDs of one of the remaining layouts, the processor 144 executes an operation 258 of determining whether a layout connection between the first layout and the one of the remaining layouts is correlated to a schematic connection between the first circuit element and the one of the remaining circuit elements of the first zone. For example, the processor 144 determines that the one of the remaining circuit elements of the first zone is connected via a first contextual connection to the first circuit element. Upon determining that the one of the remaining circuit elements of the first zone is connected via the first contextual connection to the first circuit element, the processor 144 identifies a second contextual connection that correlates to the first contextual connection from the arrow columnar formats of the schematic and layout designs. In response to identifying the second contextual connection, the processor 144 identifies that the one of the remaining layouts is connected via the second contextual connection that is identified to the first layout. In response to identifying that the one of the remaining layouts is connected via the second contextual connection that is identified to the first layout, the processor 144 identifies the one of the remaining layouts as being correlated to, such as corresponding to or having a unique relationship with or linked to, the one of the remaining circuit elements. In the example, both the first and second contextual connections are of the same type, such as an electromagnetic connection, or a stress effect, or a parasitic capacitance. The processor 144 determines that the one of the remaining layouts belongs to the layout design portion in response to identifying the one of the remaining layouts as being correlated to the one of the remaining circuit elements of the first zone.

Upon identifying the remaining layouts as being correlated with the remaining circuit elements of the first zone in the operation 258, the processor 144 executes the operation 256. On the other hand, upon determining that the remaining layouts cannot be identified as being correlated with the remaining circuit elements of the first zone in the operation 258, the processor 144 repeats the method 250 for a second zone from the zones 158 to identify additional another layout design portion as being correlated to the second zone. In this manner, the method 250 repeats for all the zones 158 selected by the user 1 to identify layout design portions correlated to the zones 158.

It should be noted that although the method 250 is described above with reference to the zones 158, the method 250 is equally applicable to any of the zones that are used to generate the facet (r+1).

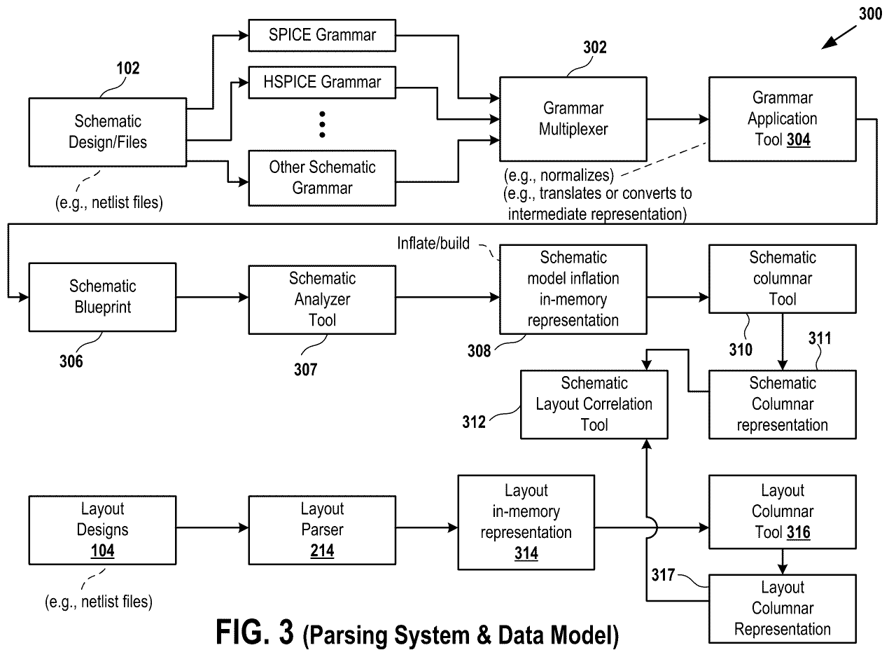

FIG. 3 is a diagram of an embodiment of a system 300 to illustrate an operation of unifying different types of grammar from the schematic files 102. The system 300 includes a grammar multiplexer tool 302, a grammar application tool 304, a schematic blueprint 306, a schematic analyzer tool 307, a schematic model inflation in-memory representation 308, a schematic columnar tool 310, a schematic columnar representation 311, a schematic-layout correlation tool 312, the layout design files 104, the layout parser 214, a layout in-memory representation 314, a layout columnar tool 316, and a layout columnar representation 317. The grammar multiplexer tool 302 is coupled to the grammar application tool 304, which is coupled to the schematic analyzer tool 307. The schematic analyzer tool 307 is coupled to the schematic columnar tool 310, which is coupled to the schematic-layout correlation tool 312. The layout parser 214 is coupled to the layout columnar tool 316.

Each of the schematic files 102 has a different type of grammar. For example, a first one of the schematic files 102 describes the schematic design in Simulation Program with Integrated Circuit Emphasis (SPICE), a second one of the schematic files 102 describes the schematic design in HSPICE, and yet another one of the schematic files 102 describes the schematic design using another type of grammar, such as Linear Technology SPICE (LTSPICE) or Personal SPICE (PSPICE). To illustrate, SPICE does not include a sweep of values of a circuit element and PSPICE does have the sweep. As another illustration, PSPICE includes additional parameters, such as a change in temperature of a circuit element, and the circuit element or the additional parameters are not available in SPICE. As another example, a first one of the schematic files 102 describes the schematic design in SPICE or HSPICE or LTSPICE or SPICE as modified by local rules or policies of a first foundry, and a second one of the schematic files 102 describes the schematic design in SPICE or HSPICE or LTSPICE or SPICE as modified by local rules or policies of a second foundry. The second foundry is an entity different from the first foundry. A type of grammar is sometimes referred to herein as a format of grammar or grammatical format.

The grammar multiplexer 302 receives the schematic files 102 having the different grammar, such as different types of grammar, and multiplexes, such as converts from a parallel manner to a serial manner, the schematic files 102 to provide the schematic files 102 to the grammar application tool 304. The grammar application tool 304 normalizes, such as translates or converts, the different grammar of the schematic files 102 to output the normalized IR in the same manner in which the schematic parser 212 (FIG. 2A) generates the normalized IR, such as the schematic blueprint 306. For example, the grammar application tool 304 identifies from a first schematic file, which describes a netlist of the schematic design in SPICE, a first circuit element, a second circuit element, and a schematic connection between the first and second circuit elements. Also, in the example, the grammar application tool 304 identifies from a second schematic file, which describes a netlist of the schematic design in HSPICE, the first circuit element, the second circuit element, and the connection between the first and second circuit elements. In response to identifying the first circuit element, the second circuit element, and the connection, the grammar application tool 304 generates the normalized IR, such as a hierarchy, having the first circuit element as a first node and a first identifier of the first circuit element, the second circuit element as a second node and a second identifier of the second circuit element, and the schematic connection as an edge, such as a line or an arrow, between the first and second circuit elements. To illustrate, grammar application tool 304 creates the tree structures and 122 and 124 (FIG. 1B-1) from the schematic files 102 in the same manner in which the preprocessor 108 executes the operation 116 (FIG. 1A) to create the normalized IR.

The grammar application tool 304 provides the schematic blueprint 306 to the schematic analyzer tool 307. The schematic analyzer tool 307 flattens the schematic blueprint 306 into the schematic model inflation in-memory representation 308 in the same manner in which the preprocessor 108 (FIG. 1A) or the schematic model building tool 213 (FIG. 2A) inflates and builds the normalized IR to flatten the hierarchical formats to output the intermediate representation of the schematic design. To illustrate, the schematic analyzer tool 307 integrates the tree structures 122 and 124 to form the intermediate representation 126 (FIG. 1B-1) in the same manner in which the preprocessor 108 executes the operation 118 (FIG. 1A) to create the intermediate representation of the schematic design. The schematic model inflation in-memory representation 308 is an example of the intermediate representation of the schematic design and the intermediate representation 126 (FIG. 1B-1) is an example of the schematic model inflation in-memory representation 308.

The schematic analyzer tool 307 sends the schematic model inflation in-memory representation 308 to the schematic columnar tool 310. The schematic columnar tool 310 generates the arrow columnar format, such as the schematic columnar representation 311, of the schematic design from the schematic model inflation in-memory representation 308 in the same manner in which the processor 144 performs the operation 146 (FIG. 1C-1).

The layout parser 214 receives the layout design files 104 and performs the operation 120 (FIG. 1A) to output the layout in-memory representation 314, which is an example of the intermediate representation of the layout design. As an example, a first one of the layout design files 104 is different from a second one of the layout design files 104. To illustrate, the first one of the layout design files 104 has a first layout format received from the first foundry and the second one of the layout design files 104 has a second layout format received from the second foundry. Examples of a layout design format include a Standard Parasitic Format (SPF), a Design-Rule Parasitic Format (DPFF), or an Enhanced Design-Rule and Parasitic Format (eDSPF). The layout parser 214 sends the layout in-memory representation 314 to the layout columnar tool 316. The layout columnar tool 316 executes the operation 152 (FIG. 1C-1) to convert the layout in-memory representation 314 into the layout columnar representation 317, which is an example of the arrow columnar representation of the layout design. Also, the schematic-layout correlation tool 312 performs the operation 157 (FIG. 1C-1) of correlating each circuit element of the schematic design with a respective layout of the layout design.

In one embodiment, the grammar multiplexer 302, the grammar application tool 304, and the schematic analyzer tool 307 are components of the schematic parser 212 and the schematic model building tool 213. For example, the functions described herein as being performed by the grammar multiplexer 302, the grammar application tool 304, and the schematic analyzer tool 307 are performed by the schematic parser 212 and the schematic model building tool 213.

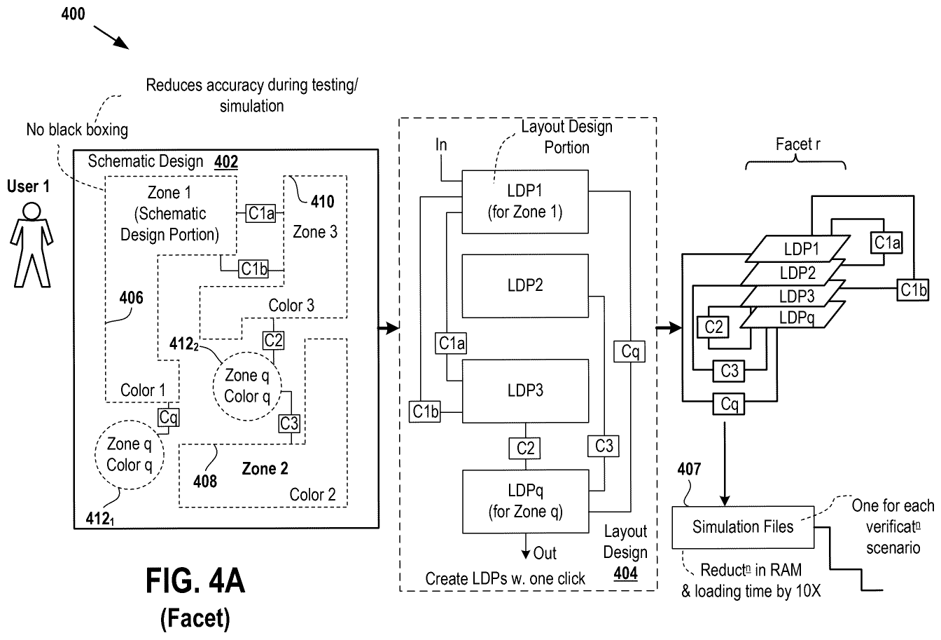

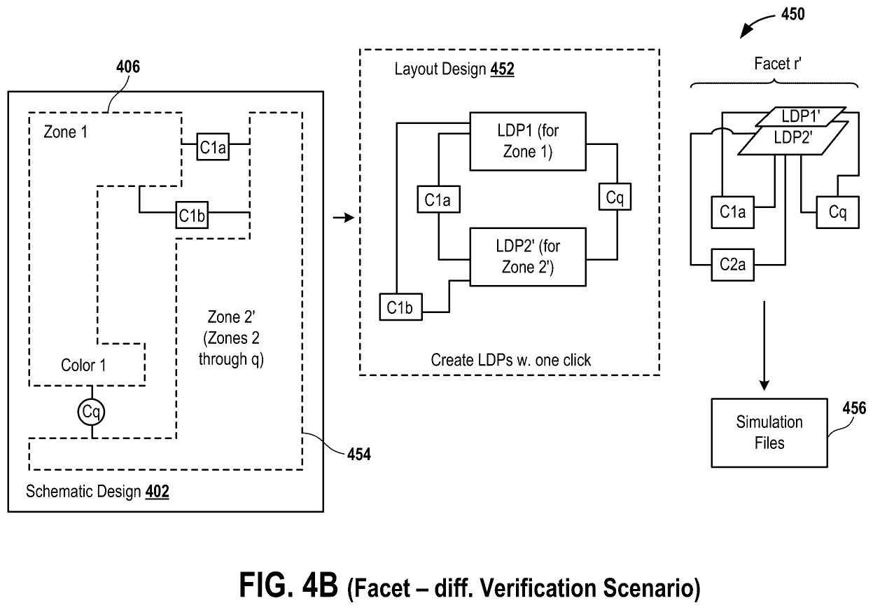

FIG. 4A is a diagram of an embodiment of a system 400 to illustrate generation of the facet r based on zones 1, 2, 3, and q that are selected by the user 1, where q is an integer greater than three. The facet r represents a first verification scenario. The zones 1 through q are examples of the zones 158 (FIG. 1C-1). The system 400 includes a schematic design 402 of the integrated circuit or the portion of the integrated circuit and a layout design 404 of the integrated circuit or the portion of the integrated circuit. The system 400 further includes the facet r.

The user 1 selects one or more buttons on the input device to access the schematic design 402 stored in the arrow columnar format in one or more of the databases 142 and 208 (FIG. 2A). Upon receiving the selection, the processor of the computer 140 sends an indication of the selection via the computer network 167 (FIG. 1C-1) to the processor 144 (FIG. 1C-1). The processor 144 accesses the schematic design 402 from the arrow columnar format in one or more of the databases 142 and 208 in response to receiving the indication of the selection and sends the schematic design 402 via the computer network 167 to the processor of the computer 140. The processor of the computer 140, upon receiving the schematic design 402, displays the schematic design 402 on the display device 169.

The user 1 uses the input device to select the zones 1 through q from the schematic design 402 displayed on the display device 169. For example, the user 1 selects one or more buttons on the input device and according to the selection, the processor of the computer 140 creates a boundary 406 around a first set of circuit elements of the schematic design 402 to identify the zone 1. Similarly, the user1 selects one or more buttons on the input device and according to the selection, the processor of the computer 140 creates a boundary 408 around a second set of circuit elements of the schematic design 402 to identify the zone 2, a boundary 410 around a third set of circuit elements of the schematic design 402 to identify the zone 3, and a boundary 412₁ and another boundary 412₂ around the q^{th} set of circuit elements of the schematic design 402 to identify the zone q. The q^{th} set includes a first subset of circuit elements of the schematic design 402 and a second subset of circuit elements of the schematic design 402. The first subset is encompassed by the boundary 412₁ and the second subset is encompassed by the boundary 412₂. Each boundary 406, 408, 410, and 412₁, and 412₂ is represented by dashed lines.

Each boundary 406, 408, 410, and 412₁, and 412₂ is generated by the processor of the computer 140 according to, such as based on, selection and/or movement of the input device. For example, when the user 1 selects a button on the input device, moves the input device to encompass the first set of circuit elements of the schematic design 402, and releases the button, the processor of the computer 140 generates the boundary 406 to identify the zone 1 and distinguishes the zone 1 from the zones 2 through q. As another example, when the user 1 selects a button on the input device and moves the input device to encompass the first and second subsets of circuit elements of the schematic design 402, and releases the button, the processor of the computer 140 generates the boundaries 412₁ and 412₂ to identify the zone q and distinguishes the zone q from the zones 1 through 3.

It should be noted that a circuit element of the zone 1 is connected to a circuit element of the zone 3 via a contextual connection C1a and to another circuit element of the zone 3 via a contextual connection C1b. A circuit element of the zone 3 is connected to a circuit element of the zone q via a contextual connection C2. Also, a circuit element of the zone q is connected to a circuit element of the zone 2 via a contextual connection C3. A circuit element of the zone 1 is connected to a circuit element of the zone q via a contextual connection Cq.

The processor of the computer 140 retains contextual connections, such as the contextual connections C1a, C1b, C2, and C3 through Cq, between the zones 1 through q and the zones 1 through q of the schematic design 402 in response to receiving the selection of the zones 1 through q from the user 1 via the input device. For example, in response to receiving a selection from the user 1 via the input device to obfuscate, using a black box or a grey box, one or more of the contextual connections C1a, C1b, C2, and C3 through Cq of the schematic design 402, the processor of the computer 140 ignores the selection and does not obfuscate the contextual connections C1a, C1b, C2, and C3 through Cq. Further, in the example, in response to receiving a selection from the user 1 via the input device to obfuscate one or more of the zones 1 through q, the processor of the computer 140 ignores the selection and does not obfuscate circuit elements in any of the zones 1 through q and does not obfuscate schematic connections between the circuit elements in any of the zones 1 through q. Also, in the example, in response receiving a selection from the user 1 via the input device to exclude a portion of a netlist of the schematic design 402, the processor of the computer 140 ignores the selection. In the example, the netlist is displayed besides the schematic design 402 on the display device 169 by the processor of the computer 140.

The processor of the computer 140 sends the zones 1 through q to the processor 144 via the computer network 167 (FIG. 1C-1). For example, in response to receiving a selection of a single button, such as a single click, of the input device from the user 1, the processor of the computer 140 sends the zones 1 through q to the processor 144 for generating the facet r. In response to receiving the selection, the processor 144 generates the facet r without a need for reextraction. As another example, in response to receiving one or more selections of one or more buttons of the input device from the user 1, the processor of the computer 140 sends the zones 1 through q to the processor 144 for generating the facet r.

In response to receiving the zones 1 through q, the processor 144 extracts, such as identifies and accesses, layouts, such as a layout design portion (LDP) 1, an LDP2, and LDP3, and an LDPq, from the arrow columnar formats of the schematic design 402 and the layout design and the correlations between the schematic design 402 and the layout design stored in the one or more of the databases 142 and 208. The processor identifies the LDPs 1 through q based on the zones 1 through q. For example, the processor 144 identifies, from the arrow columnar representation of the layout design stored in the database 142 or 208 (FIG. 2A) or both the databases, that the LDP1 correlates to the zone 1, the LDP2 correlates to the zone 2, the LDP3 correlates to the zone 3, and the LDPq correlates to the zone q. To illustrate, as described in the operation 252 (FIG. 2B), the processor 144 identifies that IDs of layouts within the LDPq matches IDs of the circuit elements within the zone q to identify that the LDPq correlates to the zone q. Also, in the example, in case one or more of the IDs of layouts within the LDPq do not match one or more of the IDs of the circuit elements within the zone q, the processor 144 applies the operation 258 (FIG. 2B) of identifying one or more of the layouts within the LDPq based on correlations between a set of schematic connections within the zone q and a set of layout connections. The set of schematic connections within the zone q is between one of the circuit elements within the zone q and remaining of the circuit elements within the zone q and the set of layout connections is between one of the layouts of the layout design and remaining of the layouts of the layout design. The one of the layouts correlates to the one of the circuit elements within the zone q. In response to determining that the correlations between the set of schematic connections within the zone q and the set of layout connections exist, the processor 144 identifies that the remaining of the layouts correlate to the remaining of the circuit elements within the zone q. Upon identifying that the layouts of the LDPq correlate to the circuit elements of the zone q, the processor 144 identifies that LDPq as being correlated to the zone q. An LDP is sometimes referred to herein as a layout region or a layout.

The processor 144 applies the same contextual connections as that between the zones 1 through q to the LDPs 1 through q to extract the LDPs1 through LDPq. For example, the processor 144 generates the contextual connection C1a between the LDP1 correlated to the zone 1 and the LDP3 correlated to the zone 3 to couple the LDP1 and the LDP3 via the contextual connection C1a. Moreover, in the example, the processor 144 generates the contextual connection C1b between the LDP1 and the LDP3 to couple the LDP1 and the LDP3 via the contextual connection C1b. Also, the processor 144 generates the contextual connection C3 between the LDP2 correlated to the zone 2 and the LDPq corresponding to the zone q to couple the LDP2 and the LDP1 via the contextual connection C3. The processor 144 generates the contextual connection C2 between the LDP3 and the LDPq correlated to the zone q to couple the LDP3 and the LDPq via the contextual connection C2. The processor 144 generates the contextual connection Cq between the LDP1 and the LDPq to couple the LDP1 and the LDPq via the contextual connection Cq. An example of the contextual connection C2 is a stress effect of the LDP3 that is on top of the LDPq because of proximity between the LDP3 and LDPq. To illustrate, when the LDP3 is close to the LDPq to be within the predetermined range, the stress effect is created.

The processor 144 creates one or more simulation files 407, such as Detailed Standard Parasitic Format (DSPF) files, having the facet r that includes the LDP1 through LDPq and the contextual connections C1a through Cq. The processor 144 stores the one or more simulation files 406 in a simulation memory device, such as a random access memory (RAM) or a read-only memory (ROM) or a combination thereof, for access by the testbench 206 (FIG. 2A). As an example, a time for loading the one or more simulation files 407 in the simulation memory device is reduced by 10 times compared to when the systems and methods, described herein, are not applied and also a lower amount of memory space in the simulation memory device is consumed by the one or more simulation files 407 compared to when the systems and methods, described herein, are not applied. Also, as an example, the memory device 141 is an example of the simulation memory device.

Because the LDPs 1 through q are stored in the arrow columnar format in one or more of the databases 142 and 208, the extraction of the LDPs is faster, such as about 50 times faster, than another type of extraction. To illustrate, all the LDPs 1 through q and the contextual connections C1 through Cq are extracted simultaneously, in parallel, from the arrow columnar format of the layout design stored in one or more of the databases and 142 and 208. To further illustrate, the processor 144 does not serially extract the LDPs 1 through q and the contextual connections C1 through Cq from the arrow columnar format of the layout design stored in one or more of the databases 142 and 208. Also, there is no need for reextraction of any of the LDP1 through q and the contextual connections C1 through Cq from one or more of the databases and 142 and 208. For example, there is a single extraction of the facet r. Moreover, there is no need for custom layouts. To illustrate, the facet r is generated based on a selection of the zones 1 through q. When the facet r is to be modified to the facet (r+1), the zones 158 are modified by the user 1 via the input device. The facet (r+1) represents a second verification scenario.

It should be noted that a size of the one or more simulation files 406 is smaller, such as by 10 times, than when the zones 1 through q are not selected. Also, the first verification scenario is less complex than an amount of complexity in case the zones 1 through q are not selected. The smaller size and the lower complexity facilitate easier testing of the one or more simulation files 406 to achieve debugging convergence faster compared to that achieved when the zones 1 through q are not selected. Also, the smaller size and the lower complexity facilitates a reduction in a memory space consumed by the one or more simulation files 406 in the simulation memory device without compromising accuracy. The accuracy is not compromised when a context, such as the contextual connections C1a, C1b, C2, C3 and Cq, of the schematic design 402 is preserved. Also, the preservation of the context facilitates viewing, via the display device 169, of top level effects, such as global routing.

It should further be noted that when the zones 158 are selected to focus on portions of the schematic design, the one or more simulation files 406 generated based on the zones 158 is smaller than schematic files generated based on a lack of selection of the zones 158. As such, an amount of memory space consumed by the one or more simulation files 406 in the simulation memory device is less compared to when layouts based on the schematic design without selection of the zones 158 are to be tested.

In one embodiment, a layout design portion is sometimes referred to herein as a layout.

In an embodiment, the terms connection and coupling or the terms connected and coupled are used herein interchangeably.

In one embodiment, a zone, as described herein, includes any number of circuit elements and schematic connections between the circuit elements.

In one embodiment, each boundary 406, 408, 410, and 412 is represented by a different graphical parameter, such as color or intensity, instead of or in addition to being represented by a dashed line. For example, the processor of the computer 140 assigns a color 1 to the zone 1, a color 2 to the zone 2, a color 3 to the zone 3, and a color q to the zone q to distinguish the zones 1 through q from each other.

In one embodiment, each boundary 406, 408, 410, and 412 is represented by a solid line instead of or in addition to being represented by a dashed line.

In an embodiment, there is a single simulation file for each verification scenario. For example, the processor 144 stores in one of the simulation files 407, the first verification scenario and stores in another one of the simulation files 407, the second verification scenario. This inclusion of a single verification scenario in a single scenario file reduces loading time of the one or more simulation files 407 in the simulation memory device by 10 times compared to when the systems and methods described herein are not used.

FIG. 4B is a diagram of an embodiment of a system 450 to illustrate that a different verification scenario, such as a third verification scenario, is created for simulation than the first verification scenario illustrated by the facet r (FIG. 4A). The system 450 includes the schematic design 402, a layout design 452 and a facet r′, which is sometimes referred to herein as r prime. The facet r′ represents the third verification scenario.

The user 1 uses the input device to select zones 1 and 2′ from the schematic design 402. For example, the processor of the computer 140 (FIG. 1C-1) displays the schematic design 402 on the display device. In addition to creating the boundary 406 to identify the zone 1, the user 1 selects one or more buttons on the input device and according to the selection, the processor of the computer 140 creates a boundary 454 around a t^{th} set of circuit elements of the schematic design 402 to identify the zone 2′, where t is an integer greater than one. The t^{th} set includes the second, third, and q^{th} sets of circuit elements of the schematic design 402. The boundary 454 is represented by dashed lines. The zones 1 and 2′ are examples of the zones 158 (FIG. 1C-1).

The boundary 454 is generated by the processor of the computer 140 according to, such as based on, the selection and/or movement of the input device. For example, when the user 1 selects a button on the input device, moves the input device to encompass the t^{th} set of circuit elements of the schematic design 402, and releases the button, the processor of the computer 140 generates the boundary 454 to identify the zone 2′ and distinguishes the zone 2′ from the zone 1.

It should be noted that a circuit element of the zone 1 is connected to a circuit element of the zone 2′ via the contextual connection C1a and to another circuit element of the zone 2′ via the contextual connection C1b. Also, a circuit element of the zone 1 is connected to a circuit element of the zone 2′ via the contextual connection Cq.

The processor of the computer 140 sends the zones 1 and 2′ to the processor 144 via the computer network 167 (FIG. 1C-1). For example, in response to receiving a selection of a single button, such as a single click, of the input device from the user 1, the processor of the computer 140 sends the zones 1 and 2′ to the processor 144 for generating the facet r′. As another example, in response to receiving one or more selections of one or more buttons of the input device from the user 1, the processor of the computer 140 sends the zones 1 and 2′ to the processor 144 for generating the facet r′.

In response to receiving the zones 1 and 2′, the processor 144 extracts, such as identifies and accesses, layouts, such as the LDP1 and an LDP2′, from one or more of the databases 142 and 208 (FIG. 2A) based on the zones 1 and 2′. For example, the processor 144 identifies, from the arrow columnar representation of the layout design stored in the database 142 or 208 or both the databases, that the LDP1 correlates to the zone 1 and the LDP2′ correlates to the zone 2′ in the same manner in which the processor 144 identifies the LDPs 1 through q based on the zones 1 through q.

The processor 144 applies the same contextual connections as those between the zones 1 and 2′ to the LDP1 and LDP2′. For example, the processor 144 generates the contextual connections C1a, C1b, and Cq between the LDP1 and the LDP2′, which correlates to the zone 2′.

The processor 144 creates one or more simulation files 456, such as DSPF files, having the facet r′ that includes the LDP1 and LDP2′ and the contextual connections C1a, C1b, and Cq. It should be noted that the LDP1 and LDP2′ and the contextual connections C1a, C1b, and Cq of the facet r′ provide the different verification scenario than the first verification scenario of the facet r. The first verification scenario includes the LDP1, LDP2, LDP3, and LDPq, and the contextual connections C1a, C1b, C2, C3, and Cq.

The processor 144 stores the one or more simulation files 456 in the simulation memory device for access by the testbench 206 (FIG. 2A). For example, the testbench 206 is controlled by the processor 144 to access the first and third verification scenarios simultaneously to test the first and third verification scenarios simultaneously. To illustrate, results of the simulation of the first and third verification scenarios are output from the testbench 206 simultaneously to provide the results to the processor of the computer 140 and display the results on the display device 169 simultaneously, such as at the same time.

It should be noted that a size of the simulation files 456 is smaller, such as by 10 times, than when the zones 1 and 2′ are not selected. Also, the different verification scenario is less complex, such as by 10 times, than an amount of complexity in case the zones 1 and 2′ are not selected. The smaller size and the lower complexity facilitate easier testing of the simulation files 456 to achieve debugging convergence faster compared to that achieved when the zones 1 and 2′ are not selected. Also, the smaller size and the lower complexity facilitates a reduction in a size of memory space consumed by the simulation files 456 in the simulation memory device without compromising accuracy. The accuracy is not compromised when the contextual connections C1a, C1b and Cq are preserved.

In one embodiment, the zone 2′ is created by the processor 140 in response to receiving a selection from the user 1 via the input device to remove one or more circuit elements from any of the zones 2 through q and/or to remove one or more contextual connections, such as the contextual connection C3 (FIG. 4A), between two or more of the zones 2 through q.

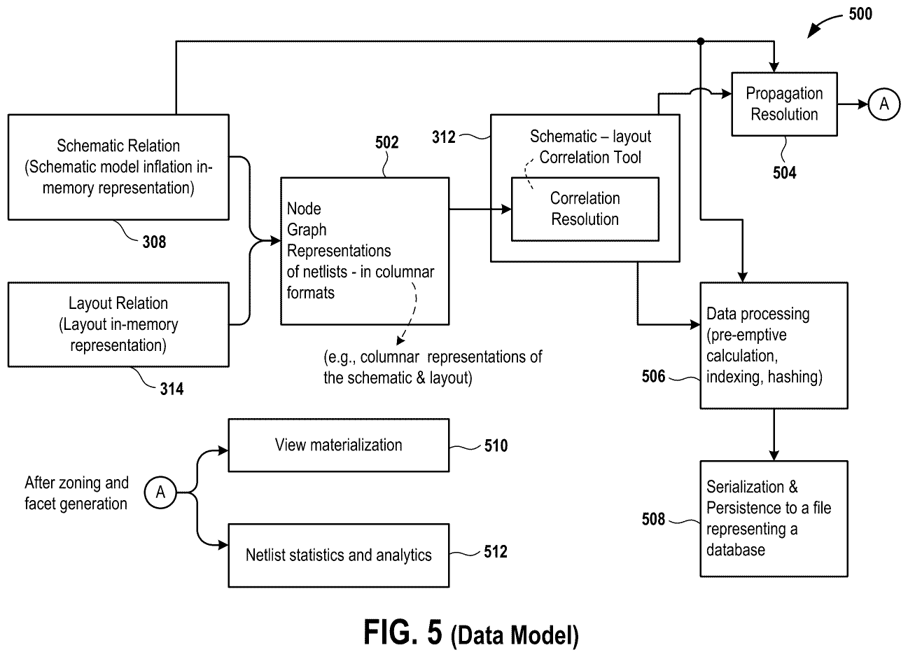

FIG. 5 is a diagram of an embodiment of a system 500 to illustrate propagation resolution, data preprocessing, materialization, and netlist statistics and analytics. The system 500 includes the schematic model inflation in-memory representation 308, the layout in-memory representation 314, node graph representations of netlists in columnar formats 502, the schematic-layout correlation tool 312, a propagation resolution tool 504, a preprocessing tool 506, a serialization and persistence tool 508, a view materialization tool 510, and a netlist statistics and analytics tool 512.

The node graph representations of netlists in columnar formats 502 include the arrow columnar formats of the schematic and layout designs. The schematic-layout correlation tool 312 is coupled to the propagation resolution tool 504 and to the data preprocessing tool 506. The data preprocessing tool 506 is coupled to the serialization and persistence tool 508.

Based on the schematic model inflation in-memory representation 308 and the layout in-memory representation 314, the node representations 502 are generated by the processor 144 (FIG. 1C-1). The schematic-layout correlation tool 312 correlates each circuit element of the schematic design with a respective layout of the layout design. The propagation resolution tool 504 propagates the input parameter signal from a node in the schematic model inflation in-memory representation 308 via an edge to another node in the schematic model inflation in-memory representation 308. For example, with reference to FIG. 1B-1, the processor 144 propagates the input parameter signal from an input of the circuit A via the edge 128₁ to the device 1 to determine if the input parameter signal is provided from an output of the device 1 and propagates the input parameter signal from the input of the circuit A via the edge 128₂ to an output of the circuit B to determine if the input parameter signal is provided from the output of the circuit B. The processor 144 propagates the input parameter signal from the output of the circuit B via the edge 128₄ to determine if the input parameter signal is provided from an output of the device 2 and propagates the input parameter signal from the output of the circuit B via the edge 128₅ to determine if the input parameter signal is provided from an output of the device 3. The processor 144 propagates the input parameter signal from the input of the circuit A via the edge 128₃ to determine if the input parameter signal is provided from an output of the additional circuit B, propagates the input parameter signal from the output of the additional circuit B via the edge 128₆ to determine if the input parameter signal is provided from an output of the additional device 2, and propagates the input parameter signal from the output of the additional circuit B via the edge 128₇ to determine if the input parameter signal is provided from an output of the additional device 3. A result of the propagation, such as whether the input parameter signal is propagated to each of the outputs, is stored in the simulation memory device for later access by the facet verification tool 220 (FIG. 2A). For example, in response to determining that the input parameter signal is propagated from the input of the circuit A to each of the outputs, the facet verification tool 220 determines that the facet r passes the simulation. On the other hand, upon determining that the input parameter signal is not propagated from the input of the circuit A to one or more of the outputs, the facet verification tool 220 determines that the facet r fails the simulation.

The data preprocessing tool 506 accesses values of circuit elements and/or the values of the output parameters at nodes of the schematic model inflation in-memory representation 308 and preprocesses, such as hashes or compresses, the values of circuit elements and/or the values of the output parameters to output hashed, such as compressed, values. The processor 144 stores the hashed values in the simulation memory device for later access by the facet verification tool 220. The hashed values are an example of the pre-determined results.

After the zones 1 through q are received from the user 1 via the input device 1 and before or after formation of the facet r, the view materialization tool 510 is executed by the processor 144 to display a final state of the schematic design with the zones 1 through q. As an example, the final state includes a number of circuit elements of each of the zones 1 through q and a relation, such as a number of contextual connections, between any two of the zones 1 through q of the schematic design. Similarly, after one or more of the zones 1 through q are modified by the user 1 via the input device, and before or after formation of the facet (r+1), the view materialization tool 510 is executed by the processor 144 to display a final state of the schematic design with the modifications to the one or more of the zones 1 through q. The netlist statistics and analytics tool 512 is executed by the processor 144 to determine a number of circuit elements removed from or added to each zone by the user 1 via the input device and a relation, such as a number of contextual connections, between any two zones of the schematic design.

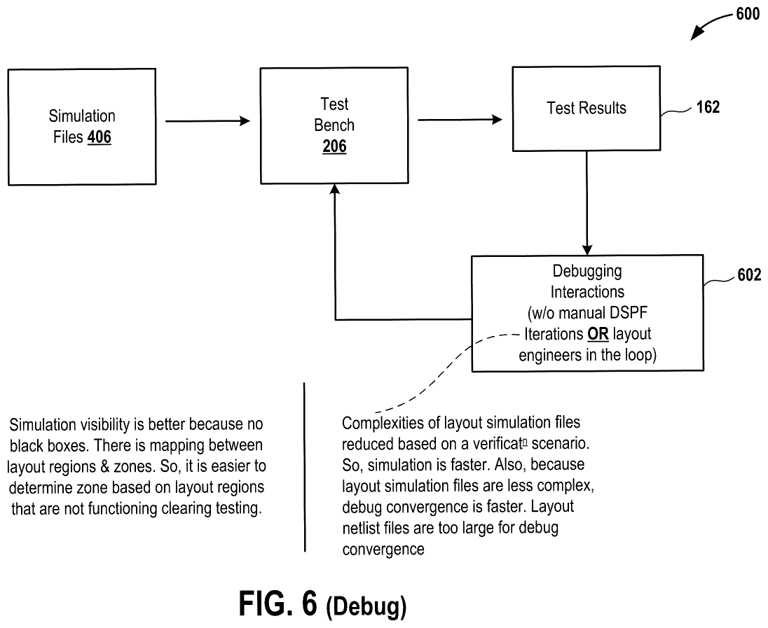

FIG. 6 is a diagram of an embodiment of a system 600 to illustrate a debugging iterations tool 602. The system 600 includes the simulation files 406, the testbench 206, the test results 162, and the debugging iterations tool 602. The debugging iterations tool 602 is coupled to the testbench 206. For example, the debugging iterations tool 602 is coupled to the facet verification tool 220 (FIG. 2A). As an example, the debugging iterations tool 602 is executed by the processor 144 (FIG. 1C-1).

The debugging iterations tool 602 receives the test results 162 and based on the test results 162 determines whether to modify one or more layouts of a facet, such as the facet r, or the facet (r+1), or the facet r′. For example, in response to receiving a determination from the facet verification tool 220 that the test results 162 do not match the predetermined results, the debugging iterations tool 602 determines to modify a criteria, such as one or more layouts, of the facet and further determines to modify one or more zones based on which the facet is generated. To illustrate, upon determining that the LDPq of the facet r is to be modified, the debugging interactions tool 602 also determines that the zone q based on which the LDPq is generated is to be modified. In the illustration, simulation visibility is provided when there are no obfuscation regions, such as black boxes, used in the layout design or the schematic design. As such, in the illustration, the zone q is identified based on the correlation between the LDPq and the zone q.

It should be noted that some of the above-described embodiments are described with respect to functions executed by a server. In various embodiments, the functions described herein as being performed by one server are performed by multiple servers, such as two or more servers. For example, one of the multiple servers performs some of the functions and another one of the servers performed remaining of the functions.

It should be noted that some of the above-described embodiments are described with respect to functions executed by a processor. In various embodiments, the functions described herein as being performed by one processor of a server are performed by multiple processors, such as two or more processors, of the server or of different servers. For example, one of the multiple processors performs some of the functions and another one of the processors performed remaining of the functions.

In one aspect, one or more embodiments described in the present disclosure are fabricated as computer-readable code on a computer-readable storage medium, which is a storage device or a memory device. The computer-readable storage medium holds data which is readable by a processor. Examples of the computer-readable storage medium include network attached storage (NAS), a memory device, a ROM, a RAM, a combination of RAM and ROM, a Compact Disc (CD), a Blu-ray™ disc, a flash memory, a hard disk, and a magnetic tape. The computer-readable storage medium, in one embodiment, is distributed over a network-coupled computer system so that the computer readable code is stored and executed in a distributed fashion.

In one embodiment, some features described in one of the embodiments described above are combined with some features described in another one of the embodiments described above.

Although the embodiments described in the present disclosure have been described in detail for purposes of clarity of understanding, it will be apparent that certain changes and modifications can be practiced within the scope of the appended claims. Accordingly, the embodiments are to be considered as illustrative and not restrictive, and the embodiments are not to be limited to the details given herein, but may be modified within the scope and equivalents of the appended claims.

1. A method for generating a facet, comprising:
receiving a selection of a plurality of zones within a schematic design of an integrated circuit, wherein any of the plurality of zones is unobfuscated, wherein the plurality of zones are coupled to each other via a plurality of contextual connections;
identifying, from a layout design of the integrated circuit, a plurality of layout regions corresponding to the plurality of zones;
coupling the plurality of layout regions via the plurality of contextual connections; and
forming the facet based on the plurality of layout regions and the plurality of contextual connections.

2. The method of claim 1, further comprising providing the facet to a testbench to test the facet, wherein the plurality of contextual connections are nonphysical connections.

3. The method of claim 1, wherein the plurality of zones include a first zone, a second zone, and a third zone, wherein the plurality of contextual connections include a first contextual connection and a second contextual connection, wherein the first zone is coupled to the second zone via the first contextual connection and is coupled to the third zone via the second contextual connection, wherein the first contextual connection lacks a physical connection between the first zone and the second zone and the second contextual connection lacks a physical connection between the first zone and the third zone.

4. The method of claim 3, wherein the first zone includes a first circuit element, the second zone includes a second circuit element, and the third zone includes a third circuit element, wherein the first contextual connection is an electromagnetic coupling or a stray capacitance between the first circuit element and the second circuit element and the second contextual connection is an electromagnetic coupling or a stray capacitance between the first circuit element and the third circuit element.

5. The method of claim 1, wherein the plurality of zones are a first set of zones, the method further comprising:
receiving a modification to one of the plurality of zones to output a second set of zones; and
determining integrity of the second set of zones.

6. The method of claim 1, wherein the plurality of zones include a first zone and a second zone, wherein the first zone includes a first plurality of circuit elements and a first plurality of connections between the first plurality of circuit elements and the second zone includes a second plurality of circuit elements and a second plurality of connections between the second plurality of circuit elements, wherein the first plurality of circuit elements, the first plurality of connections, the second plurality of circuit elements, and the second plurality of connections are not obfuscated.

7. The method of claim 1, wherein the facet includes the plurality of layout regions and the plurality of contextual connections, wherein the plurality of contextual connections are nonphysical and interactive connections.

8. The method of claim 1, wherein the plurality of contextual connections are nonphysical connections that lack a metal conductor.

9. The method of claim 1, further comprising:
parsing a plurality of schematic files to form a normalized intermediary representation having a hierarchical format of the schematic design and to identify a plurality of schematic regions of the schematic design, wherein the plurality of zones are selected from the plurality of schematic regions, wherein each of the plurality of schematic files has a different grammatical format of the schematic design, wherein the normalized intermediate representation unifies the different grammatical formats; and
inflating and building the normalized intermediary representation to flatten the hierarchical format to provide an intermediate representation of the schematic design.

10. The method of claim 9, further comprising:
converting the intermediate representation of the schematic design to an arrow columnar format of the schematic design, wherein in the arrow columnar format, the plurality of contextual connections are represented in a column, wherein the arrow columnar format facilitates faster searching of the plurality of contextual connections compared to when the arrow columnar format is not used.

11. The method of claim 10, further comprising:
parsing a plurality of layout files to form an intermediate representation of the layout design.

12. The method of claim 11, further comprising:
converting the intermediate representation of the layout design to an arrow columnar format of the layout design;
correlating each of a plurality of circuit elements of the schematic design with a respective one of the plurality of layout regions of the layout design to create a plurality of correlations; and
storing the arrow columnar format of the schematic design, the arrow columnar format of the layout design, and the plurality of correlations in a database.

13. The method of claim 12, further comprising:
upon receiving the selection of the plurality of zones, accessing the arrow columnar format of the schematic design, the arrow columnar format of the layout design, and the plurality of correlations from the database for said identifying the plurality of layout regions.

14. The method of claim 12, further comprising modifying a circuit identifier of a circuit element in one of the plurality of zones in response to receiving a selection of a button of an input device, wherein said modifying the circuit identifier includes simultaneously modifying the circuit identifier in a first row in the arrow columnar format of the schematic design and a second row of the arrow columnar format of the schematic design.

15. The method of claim 1, wherein upon receiving the selection of the plurality of zones:
determining that a first identifier of one of the plurality of circuit elements does not match a second identifier of one of the plurality of layout regions;
identifying one of the plurality of contextual connections between the one of the plurality of circuit elements and another one of the plurality of circuit elements in response to determining that the first identifier does not match the second identifier;
identifying the one of the plurality of layout regions after identifying the one of the plurality of contextual connections.

16. A controller for generating a facet, comprising:
a processor configured to:
receive a selection of a plurality of zones within a schematic design of an integrated circuit, wherein any of the plurality of zones is unobfuscated, wherein the plurality of zones are coupled to each other via a plurality of contextual connections;
identify, from a layout design of the integrated circuit, a plurality of layout regions corresponding to the plurality of zones;
couple the plurality of layout regions via the plurality of contextual connections; and
form the facet based on the plurality of layout regions and the plurality of contextual connections; and
a memory device coupled to the processor.

17. The controller of claim 16, wherein the processor is configured to provide the facet to a testbench to test the facet, wherein the plurality of contextual connections are nonphysical connections.

18. The controller of claim 16, wherein the plurality of zones include a first zone, a second zone, and a third zone, wherein the plurality of contextual connections include a first contextual connection and a second contextual connection, wherein the first zone is coupled to the second zone via the first contextual connection and is coupled to the third zone via the second contextual connection, wherein the first contextual connection lacks a physical connection between the first zone and the second zone and the second contextual connection lacks a physical connection between the first zone and the third zone.

19. The controller of claim 18, wherein the first zone includes a first circuit element, the second zone includes a second circuit element, and the third zone includes a third circuit element, wherein the first contextual connection is an electromagnetic coupling or a stray capacitance between the first circuit element and the second circuit element and the second contextual connection is an electromagnetic coupling or a stray capacitance between the first circuit element and the third circuit element.

20. The controller of claim 16, wherein the plurality of zones include a first zone and a second zone, wherein the first zone includes a first plurality of circuit elements and a first plurality of connections between the first plurality of circuit elements and the second zone includes a second plurality of circuit elements and a second plurality of connections between the second plurality of circuit elements, wherein the first plurality of circuit elements, the first plurality of connections, the second plurality of circuit elements, and the second plurality of connections are not obfuscated.

21. The controller of claim 16, wherein the facet includes the plurality of layout regions and the plurality of contextual connections, wherein the plurality of contextual connections are nonphysical and interactive connections.

22. The controller of claim 16, wherein the processor is configured to:
parse a plurality of schematic files to form a normalized intermediary representation having a hierarchical format of the schematic design and to identify a plurality of schematic regions of the schematic design, wherein the plurality of zones are selected from the plurality of schematic regions, wherein each of the plurality of schematic files has a different grammatical format of the schematic design; and
inflate and build the normalized intermediary representation to flatten the hierarchical format to provide an intermediate representation of the schematic design.

23. The controller of claim 22, wherein the processor is configured to:
convert the intermediate representation of the schematic design to an arrow columnar format of the schematic design.

24. The controller of claim 23, wherein the processor is configured to:
parse a plurality of layout files to form an intermediate representation of the layout design.

25. The controller of claim 24, wherein the processor is configured to:
convert the intermediate representation of the layout design of the layout design to an arrow columnar format of the layout design;
correlate each of a plurality of circuit elements of the schematic design with a respective one of the plurality of layout regions of the layout design to create a plurality of correlations; and
store the arrow columnar format of the schematic design, the arrow columnar format of the layout design, and the plurality of correlations in a database.

26. The controller of claim 25, wherein in response to receiving the selection of the plurality of zones, the processor is configured to access the arrow columnar format of the schematic design, the arrow columnar format of the layout design, and the plurality of correlations from the database for the identification of the plurality of layout regions.

27. The controller of claim 25, wherein the processor is configured to:
modify a circuit identifier of a circuit element in one of the plurality of zones in response to receiving a selection of a button of an input device, wherein to modify the circuit identifier, the processor is configured to simultaneously modify the circuit identifier in a first row in the arrow columnar format of the schematic design and a second row of the arrow columnar format of the schematic design.

28. The controller of claim 16, wherein in response to receiving the selection of the plurality of zones, the processor is configured to:
determine that a first identifier of one of the plurality of circuit elements does not match a second identifier of one of the plurality of layout regions;
identify one of the plurality of contextual connections between the one of the plurality of circuit elements and another one of the plurality of circuit elements in response to determining that the first identifier does not match the second identifier;
identify the one of the plurality of layout regions after identifying the one of the plurality of contextual connections.

29. A system for generating a facet, comprising:
a computer configured to receive a selection of a plurality of zones within a schematic design of an integrated circuit, wherein any of the plurality of zones is unobfuscated, wherein the plurality of zones are coupled to each other via a plurality of contextual connections; and
a server coupled to the computer via a computer network, wherein the server is configured to:
identify, from a layout design of the integrated circuit, a plurality of layout regions corresponding to the plurality of zones;
couple the plurality of layout regions via the plurality of contextual connections; and
form the facet based on the plurality of layout regions and the plurality of contextual connections.

30. The system of claim 29, wherein the plurality of zones include a first zone, a second zone, and a third zone, wherein the plurality of contextual connections include a first contextual connection and a second contextual connection, wherein the first zone is coupled to the second zone via the first contextual connection and is coupled to the third zone via the second contextual connection, wherein the first contextual connection lacks a physical connection between the first zone and the second zone and the second contextual connection lacks a physical connection between the first zone and the third zone.
